(19) United States
(12) Patent Application Publication
(10) Pub. No.: US 2026/0136712 A1
(43) Pub. Date: May 14, 2026

(54) LIGHT-EMITTING ELEMENT AND DISPLAY DEVICE

(71) Applicant: Sharp Display Technology Corporation, Kameyama City, Mie (JP)

(72) Inventor: Kazuki MARUHASHI, Sakai City, Osaka (JP)

(21) Appl. No.: 19/119,864

(22) PCT Filed: Oct. 19, 2022
(86) PCT No.: PCT/JP2022/038898

§ 371 Date: Apr. 10, 2025

(51) Int. Cl. H10H 20/812; H10H 20/816

(52) U.S. Cl. CPC H10H 20/812; H10H 20/816

(57) ABSTRACT

The light-emitting element includes an anode, a cathode, and a light-emitting layer positioned between the anode and the cathode. The light-emitting layer includes a plurality of quantum dots and an inorganic filler. The inorganic filler fills spaces between the plurality of quantum dots and contains at least one of a metal sulfide and a metal oxide. In the inorganic filler, a concentration of at least one of sulfur atoms and oxygen atoms gradually decreases in a direction from the anode toward the cathode.

### TECHNICAL FIELD

The disclosure relates to a light-emitting element and a display device including the light-emitting element.

### BACKGROUND ART

In a light-emitting element including a light-emitting layer containing quantum dots as a light-emitting material, carriers may pass through the light-emitting layer without being injected into the quantum dots, thereby generating a reactive current. The generation of the reactive current causes the problem of deterioration of the quantum dots or the peripheral layer of the light-emitting layer in addition to a decrease in the luminous efficiency of the light-emitting element, leading to a decrease in the reliability of the light-emitting element. PTL 1 discloses a light-emitting element in which a light-emitting layer includes a plurality of quantum dots each having a shell having a different thickness to improve confinement of carriers in the quantum dots.

### CITATION LIST

### Patent Literature

PTL 1: JP 6233417 B

### SUMMARY

### Technical Problem

It can be said that the light-emitting element disclosed in PTL 1 has a configuration that prevents a reactive current from being generated by reducing the outflow of carriers injected into the quantum dots to the outside of the quantum dots. Therefore, in the light-emitting element disclosed in PTL 1, it is difficult to reduce a reactive current flowing between the quantum dots.

### Solution to Problem

In one aspect of the disclosure, a light-emitting element includes an anode, a cathode, and a light-emitting layer positioned between the anode and the cathode, in which the light-emitting layer includes a plurality of quantum dots and an inorganic filler, the inorganic filler fills a space between the plurality of quantum dots and includes at least one of a metal sulfide and a metal oxide, and in the inorganic filler, a concentration of at least one of sulfur atoms and oxygen atoms decreases in a direction from the anode toward the cathode.

In another aspect of the disclosure, a light-emitting element includes an anode, a cathode, and a light-emitting layer positioned between the anode and the cathode, in which the light-emitting layer includes a plurality of quantum dots and an inorganic filler, the inorganic filler fills a space between the plurality of quantum dots and includes at least one of a metal sulfide and a metal oxide, and in the inorganic filler, there is a portion in which a concentration of at least one of sulfur atoms and oxygen atoms on a cathode side is lower than a concentration of the same atoms as the at least one of sulfur atoms and oxygen atoms on an anode side.

In another aspect of the disclosure, a light-emitting element includes an anode, a cathode, and a light-emitting layer positioned between the anode and the cathode, in which the light-emitting layer includes a plurality of quantum dots and an inorganic filler, the inorganic filler fills a space between the plurality of quantum dots and includes at least one of a metal sulfide and a metal oxide, and in the inorganic filler, a density of atomic defects of at least one of sulfur atoms and oxygen atoms increases in a direction from the anode toward the cathode.

In another aspect of the disclosure, a light-emitting element includes an anode, a cathode, and a light-emitting layer positioned between the anode and the cathode, in which the light-emitting layer includes a plurality of quantum dots and an inorganic filler that includes a chalcogenide and fills a space between the plurality of quantum dots, and in the inorganic filler, a concentration of atoms of a chalcogen element decreases in a direction from the anode toward the cathode.

In another aspect of the disclosure, a light-emitting element includes an anode, a cathode and a light-emitting layer positioned between the anode and the cathode, in which the light-emitting layer includes a plurality of quantum dots and an inorganic filler, the inorganic filler fills a space between the plurality of quantum dots, includes a ternary compound semiconductor including a metal atom, and has a concentration gradient of the metal atom in a direction from the anode toward the cathode, and a band gap of the inorganic filler becomes smaller in the direction from the anode toward the cathode.

A method for manufacturing a light-emitting element in another aspect of the disclosure is a method for manufacturing a light-emitting element including an anode, a cathode, and a light-emitting layer positioned between the anode and the cathode, the light-emitting layer including a plurality of quantum dots and an inorganic filler, the inorganic filler filling a space between the plurality of quantum dots and including at least one of a metal sulfide and a metal oxide, the method including applying a first solution including the plurality of quantum dots and a first inorganic precursor; forming a first portion of the light-emitting layer by denaturing the first inorganic precursor into the inorganic filler by heating the first solution at a first temperature; applying a second solution including a second inorganic precursor onto the first portion; and forming a second portion of the light-emitting layer on the first portion by denaturing the second inorganic precursor into the inorganic filler by heating the second solution at a second temperature higher than the first temperature.

A method for manufacturing a light-emitting element in another aspect of the disclosure is a method for manufacturing a light-emitting element that includes an anode, a cathode, and a light-emitting layer positioned between the anode and the cathode, the light-emitting layer including a plurality of quantum dots and an inorganic filler, the inorganic filler filling a space between the plurality of quantum dots, including a ternary compound semiconductor including a metal atom, and having a concentration gradient of the metal atom in a direction from the anode toward the cathode, the method including applying a first solution including the plurality of quantum dots and a first inorganic precursor including a plurality of metal sources; forming a first portion of the light-emitting layer by denaturing the first inorganic precursor into the inorganic filler by heating the first solution; applying a second solution including a second inorganic precursor including a plurality of the metal sources and including a different proportion of the metal sources from the first solution onto the first portion; and forming a second portion of the light-emitting layer on the first portion by denaturing the second inorganic precursor into the inorganic filler by heating the second solution, in which a band gap of the inorganic filler of the second portion is smaller than a band gap of the inorganic filler of the first portion.

### Advantageous Effects of Disclosure

The luminous efficiency and reliability of the light-emitting element are improved by curbing a reactive current flowing between quantum dots of a light-emitting layer.

### BRIEF DESCRIPTION OF DRAWINGS

FIG. 1 illustrates a schematic side cross-sectional view of a display device according to a first embodiment, a schematic cross-sectional view of quantum dots, and a schematic diagram for showing an inorganic filler with which spaces between quantum dots are filled in parallel.

FIG. 2 is a schematic plan view of the display device according to the first embodiment.

FIG. 3 is a flowchart explaining an example of a method for manufacturing a light-emitting element according to the first embodiment.

FIG. 4 is a schematic side cross-sectional view of a display device according to a second embodiment.

FIG. 5 is a schematic side cross-sectional view of a display device according to a third embodiment.

FIG. 6 is a schematic band diagram of layers of a light-emitting element according to a modified example of the third embodiment.

FIG. 7 is a schematic side cross-sectional view of a display device according to a fourth embodiment.

### DESCRIPTION OF EMBODIMENTS

### First Embodiment

### Display Device

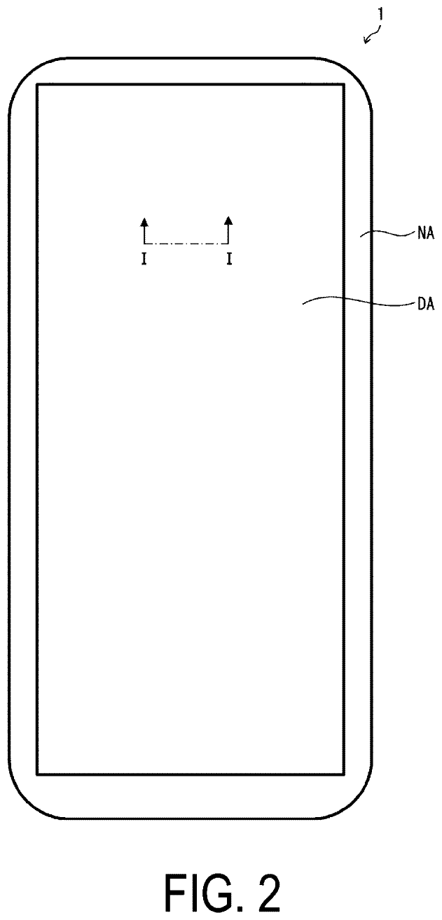

Embodiments of the disclosure will be described below with reference to the drawings. In each drawing, the same components are denoted by the same reference numerals and signs, and description thereof is omitted. FIG. 2 is a schematic plan view of a display device according to the present embodiment.

A display device 1 is a device that can be used as a display of, for example, a television, a smartphone, or the like. The display device 1 includes a display portion DA and a frame portion NA formed around the display portion DA. The display device 1 performs display in the display portion DA by controlling light emission from each of a plurality of light-emitting elements, which will be described below, formed in the display portion DA. In the frame portion NA, a driver or the like for driving each of the plurality of light-emitting elements of the display portion DA may be formed.

The display portion DA of the display device 1 according to the present embodiment may include a plurality of subpixels including red subpixels, green subpixels, and blue subpixels. A light-emitting element, which will be described below, is formed in each subpixel, and each light-emitting element individually emits light. Thus, the display device 1 performs display by individually controlling light emission from the plurality of light-emitting elements of the display portion DA by using, for example, a driver or the like formed in the frame portion NA.

### Light-Emitting Element: Overview

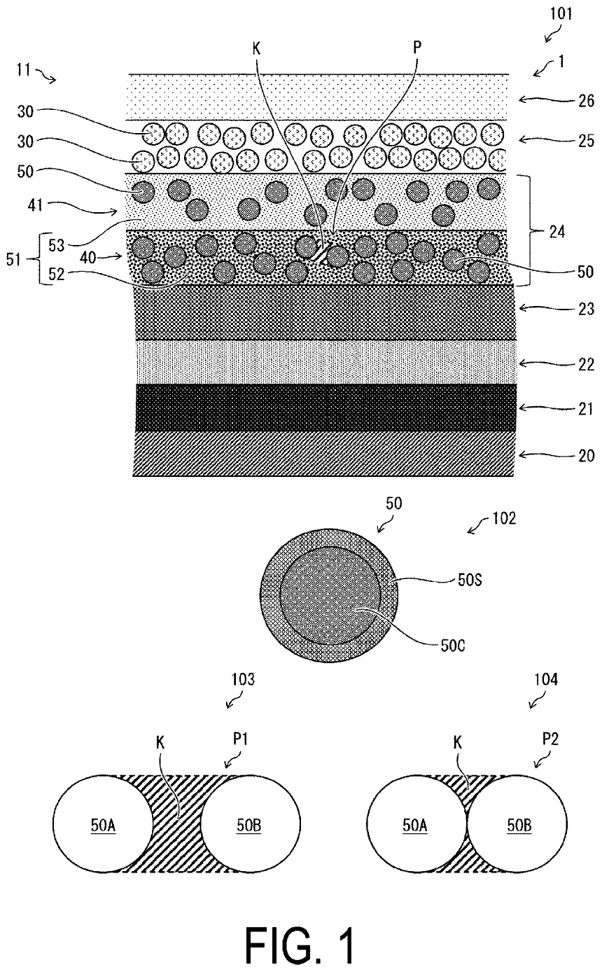

A structure of the display portion DA of the display device 1 according to the present embodiment will be described in detail with reference to FIG. 1. FIG. 1 includes a schematic side cross-sectional view 101 of the display device 1 according to the present embodiment, a schematic cross-sectional view 102 of quantum dots 50, which will be described below, and a schematic view 103 and a schematic view 104 for showing an inorganic filler 51 with which spaces between the quantum dots 50 are filled. In the disclosure, a direction from a substrate 20, which will be described below, of the display device 1 toward a cathode 26 may be described as an “upward direction”, and the direction opposite thereto may be described as a “downward direction”.

The schematic side cross-sectional view 101 is a cross-sectional view taken along line I-I shown in FIG. 2, and is a view showing a cross-section passing through a light-emitting element 11 in a plan view of the substrate 20 of the display device 1 according to the present embodiment. Note that the schematic side cross-sectional views of the display device in the disclosure shows a cross-section of the display device corresponding to the cross-section shown in the schematic side cross-sectional view 101.

The schematic cross-sectional view 102 is a view illustrating a cross-section of a quantum dot 50 passing through substantially the center of the quantum dot 50. The schematic view 103 and the schematic view 104 are views respectively illustrating two examples of a set P of two quantum dots 50 and the region (space) K therebetween illustrated in the schematic side cross-sectional view 101. In particular, the schematic view 103 and the schematic view 104 are views each illustrating a pair P1 and a pair P2, which are examples of pairs of quantum dots 50A and quantum dots 50B.

As illustrated in the schematic side cross-sectional view 101, the display device 1 includes the light-emitting element 11. In the present embodiment, the light-emitting element 11 includes a substrate 20. For example, it may be considered that the substrate 20 is formed at a position overlapping the display portion DA and the frame portion NA in a plan view of the display device 1, and the light-emitting element 11 includes a portion of the substrate 20 overlapping the display portion DA in a plan view of the display device 1. In other words, the substrate 20 may be formed over the display portion DA and the frame portion NA in a plan view of the display device 1. An upper surface of the substrate 20 may be substantially parallel to the display surface of the display device 1, and in other words, a plan view of the substrate 20 may be substantially the same as a plan view of the display device 1.

Furthermore, the light-emitting element 11 includes an anode 21, a hole injection layer 22, a hole transport layer 23, a light-emitting layer 24, an electron transport layer 25, and the cathode 26 in this order from the substrate 20 side. Note that the present embodiment is not limited thereto, and the light-emitting element 11 may include a cathode, an electron transport layer, a light-emitting layer, a hole transport layer, a hole injection layer, and an anode in this order from the substrate 20 side. The light-emitting element 11 may further include an electron injection layer between the electron transport layer 25 and the cathode 26.

The light-emitting element 11 may be individually formed in each of the plurality of subpixels described above. In addition, the display device 1 may include a driver or the like, which is not illustrated, at a position on the substrate 20 overlapping the frame portion NA in a plan view. The substrate 20 may include a pixel circuit, which is not illustrated, corresponding to each subpixel. The pixel circuit may be electrically connected to the anode 21 of the light-emitting element 11. The display device 1 may control light emission from each light-emitting element 11 by controlling voltage application to the anode 21 by each pixel circuit under control of the driver or the like.

### Light-Emitting Element: Anode and Cathode

At least one of the anode 21 and the cathode 26 is a transparent electrode through which visible light passes. As the transparent electrode, for example, ITO, InZnO, SnO₂, or FTO may be used. Alternatively, any one of the anode 21 and the cathode 26 may be a reflective electrode. The reflective electrode may contain a metal material having a high reflectance of visible light, and the metal material may be, for example, Al, Ag, Cu, or Au alone or an alloy thereof.

### Light-Emitting Element: Charge Transport Layer

The hole injection layer 22 is a layer through which holes from the anode 21 are injected into the light-emitting layer 24 side. As the material of the hole injection layer 22, an organic or inorganic material having the hole transport properties employed in the related art in a light-emitting element containing quantum dots can be used. The hole injection layer 22 may contain nanoparticles of nickel oxide (NiO). In addition, the hole injection layer 22 may contain a self-assembled monolayer of [2-(3,6-dimethoxy-9H-carbosol-9-yl)ethyl] phosphonate (MeO-2PACz). In addition, examples of the material of the hole injection layer 22 include a composite of poly(3,4-ethylenedioxythiophene) (PEDOT) and polystyrene sulfonic acid (PSS) (abbreviated as “PEDOT:PSS”), copper thiocyanate (CuSCN), and the like. Furthermore, the hole injection layer 22 may contain bulk NiO (nickel oxide), which is not nanoparticles, as a material. Note that one type of these materials may be used, or two or more types thereof may be mixed and used as appropriate.

The hole transport layer 23 is a layer through which holes injected from the anode 21 to the hole injection layer 22 are transported to the light-emitting layer 24 side. As the material of the hole transport layer 23, an organic or inorganic material having the hole transport properties employed in the related art in a light-emitting element containing quantum dots can be used. Examples of the material of the hole transport layer 23 include poly [(9,9-dioctylfluorenyl-2,7-diyl)-co-(4,4′-(N-4-sec-butylphenyl)) diphenylamine)] (abbreviated as “TFB”), poly [N,N′-bis(4-butylphenyl)-N,N′-bis(phenyl)-benzidine] (abbreviated as “poly-TPD”), polyvinyl carbazole (abbreviated to “PVK”), and the like. One type of these materials may be used alone, or two or more types thereof may be mixed or layered and used as appropriate.

The electron transport layer 25 is a layer through which electrons injected from the cathode 26 are transported to the light-emitting layer 24. The electron transport layer 25 according to the present embodiment includes nanoparticles 30 as an electron transport material. In addition, the electron transport layer 25 may include a ligand capable of coordinating with the nanoparticles 30.

For example, the nanoparticles 30 may be nanoparticles of zinc oxide (ZnO), zinc oxide (ZnO) doped with at least one of Li, Mg, Al, Ti, Ga, and Zr, titanium oxide (TiO₂), or zirconium oxide (ZrO₂). Note that chemical formulas written in the disclosure are representative examples. In addition, in the disclosure, the composition ratios shown in the chemical formulas do not necessarily have to be stoichiometric, that is, the composition of the actual compound may not be exactly as shown in the chemical formula.

Note that the electron transport material contained in the electron transport layer 25 is not limited to the nanoparticles 30. For example, as the electron transport material, the electron transport layer 25 can use an organic or inorganic material having the electron transport properties employed in the related art in a light-emitting element containing quantum dots. The electron transport material may include, for example, 2,2′,2″-(1,3,5-benzintriyl)-tris (1-phenyl-1-H-benzimidazole) (abbreviated as “TPBi”), 2,9-dimethyl-4,7-diphenyl-1,10-phenanthroline (abbreviated as “BCP”), 4,7-diphenyl-1,10-phenanthroline (abbreviated as “Bphen”), or the like. Alternatively, the electron transport layer 25 may include bulk zinc oxide (ZnO), zinc oxide (ZnO), titanium oxide (TiO₂), or zirconium oxide (ZrO₂), which are not nanoparticles, as the electron transport material. The bulk zinc oxide (ZnO) may be doped with at least one of Li, Mg, Al, Ti, Ga, and Zr. Only one type of the above-described electron transport materials may be used, or two or more types thereof may be included as appropriate.

### Light-Emitting Element: Light-Emitting Layer: Quantum Dots

The light-emitting layer 24 includes a first light-emitting layer 40 as a first portion and a second light-emitting layer 41 as a second portion in this order from the anode 21 side. Both the first light-emitting layer 40 and the second light-emitting layer 41 contain a plurality of quantum dots 50 as a light-emitting material. For example, as shown in a schematic cross-sectional view 102, the quantum dot 50 has a core/shell structure including a core 50C and a shell 50S formed in at least a single layer covering the periphery of the core 50C. The shell 50S may have a plurality of layers from the center to the periphery of the core 50C. Each of the first light-emitting layer 40 and the second light-emitting layer 41 may contain a ligand capable of coordinating with the shell 50S as the outermost layer of the quantum dot 50.

The core 50C of each quantum dot 50 receives injection of holes from the anode 21 and electrons from the cathode 26 and emits light due to excitons generated from recombination in which the holes and the electrons recombine with each other. The shell 50S of the quantum dot 50 may have a function of protecting the core 50C, such as compensating for defects of the core 50C. In addition, the quantum dot 50 may have various known structures.

Note that, in the disclosure, a “quantum dot” refers to a dot having a maximum width of 100 nm or less. For example, a shape of the quantum dot 50 is not particularly limited as long as it is within a range satisfying the maximum width, and the shape is not limited to a spherical three-dimensional shape (circular cross-sectional shape). The shape of the quantum dot 50 may be, for example, a polygonal cross-sectional shape, a rod-like three-dimensional shape, a branch-like three-dimensional shape, a three-dimensional shape having unevenness on the surface, or a combination thereof.

The quantum dot 50 may be typically made of a semiconductor. The semiconductor may have a constant band gap. The semiconductor may be a material capable of emitting light and may include at least a material which will be described below. The semiconductor may emit each of blue light, green light, and red light. The semiconductor includes, for example, at least one kind selected from the group consisting of a group II-VI compound, a group III-V compound, and chalcogenide and perovskite compounds. Note that the group II-VI compound refers to a compound including a group II element and a group VI element, and the group III-V compound refers to a compound including a group III element and a group V element. Further, the group II element may include a group 2 element and a group 12 element, the group III element may include a group 3 element and a group 13 element, the group V element may include a group 5 element and a group 15 element, and the group VI element may include a group 6 element and a group 16 element.

Examples of the group II-VI compound include at least one kind selected from the group consisting of MgS, MgSe, MgTe, CaS, CaSe, CaTe, SrS, SrSe, SrTe, BaS, BaSe, BaTe, ZnS, ZnSe, ZnTe, CdS, CdSe, CdTe, HgS, HgSe, and HgTe.

Examples of the group III-V compound include at least one kind selected from the group consisting of GaAs, GaP, GaSb, InN, InAs, InP, and InSb.

The chalcogenide is a compound including a group VI A (16) element, and includes, for example, CdS or CdSe. The chalcogenide may include a mixed crystal thereof.

The perovskite compound has, for example, a composition represented by a general formula CsPbX₃, CsSnX₃, CH₃NH₃PbX₃, or CH₃NH₃SnX₃. Examples of the constituent element X include at least one kind selected from the group consisting of Cl, Br, and I.

Here, the numbering of element groups using Roman numerals is numbering based on the old International Union of Pure and Applied Chemistry (IUPAC) system or old Chemical Abstracts Service (CAS) system, and the numbering of element groups using Arabic numerals is numbering based on the current IUPAC system.

In the present embodiment, the concentration of the quantum dots 50 in the first light-emitting layer 40 is higher than the concentration of the quantum dots 50 in the second light-emitting layer 41. For this reason, the light-emitting layer 24 may have a portion with a concentration of the quantum dots 50 decreasing or gradually decreasing in the direction from the anode 21 to the cathode 26, or the concentration may decrease or gradually decrease throughout the light-emitting layer 24. Hereinafter, although a case in which the concentration becomes gradually lower throughout the light-emitting layer 24 will be described as an example, the disclosure is not necessarily limited to this configuration.

In the disclosure, although a case in which the concentration of the material in each portion of the light-emitting layer 24 becomes “gradually lower” will be described as an example, the disclosure is not necessarily limited to this configuration. In the disclosure, as long as there is no contradiction, the case in which the concentration of a corresponding material becomes “gradually lower” does not exclude the cases in which the light-emitting layer 24 has a portion with a decreasing concentration, has a portion with a gradually decreasing concentration, has a concentration decreasing throughout the light-emitting layer 24, and has a concentration gradually decreasing throughout the light-emitting layer 24. In addition, the concentration “gradually decreasing” at the boundary of the light-emitting layer 24 with the adjacent layer may refer to a change in concentration that is not related to the composition of a separately desired concentration. That is, since the concentration of sulfur atoms and oxygen atoms does not necessarily steeply change at the boundary, the region ranging from the interface to 1.2 nm or less may be excluded from the light-emitting layer 24.

Note that, in the disclosure, the concentration of a material in each portion of the light-emitting layer 24 is, for example, an area ratio occupied by the material in a cross section of the light-emitting layer 24. In addition, in the disclosure, the “concentration of a material gradually decreasing” in each portion of the light-emitting layer 24 means that the concentration slowly or stepwisely decreases and is not limited to having a portion in which the concentration of the material is substantially the same. Here, the portion having substantially the same concentration of the material refers to a portion in which a difference in area ratios occupied by the material in the region of 200 nm² is within 5% in cross-sectional observation of the light-emitting layer 24.

In a cross-section of the first light-emitting layer 40, the area ratio occupied by the quantum dots 50 may be 60% or more from the viewpoint of reducing a reactive current in which carriers are not injected into the quantum dots and do not contribute to light emission. In addition, the area ratio may be 90% or less from the viewpoint of enhancing the effect of protecting the quantum dots 50 by the inorganic filler 51 to be described below. Furthermore, in a cross-section of the second light-emitting layer 41, the area ratio occupied by the quantum dots 50 may be 5% or more, and may be 60% or less from the viewpoint of enhancing the effect of protecting the quantum dots 50 by the inorganic filler 51 against foreign matter from the cathode 26 side to be described below.

### Light-Emitting Element: Light-Emitting Layer: Inorganic Filler

The light-emitting layer 24 includes the inorganic filler 51 filling the spaces between the plurality of quantum dots 50. In other words, the light-emitting layer 24 includes the inorganic filler 51 as an inorganic matrix material filling the spaces between the plurality of quantum dots 50. The inorganic filler 51 includes a first inorganic filler 52 and a second inorganic filler 53. In particular, the first light-emitting layer 40 includes the first inorganic filler 52 of the inorganic filler 51, and the second light-emitting layer 41 includes the second inorganic filler 53 of the inorganic fillers 51. In other words, the first light-emitting layer 40 includes a plurality of quantum dots 50 and the first inorganic filler 52 filling the spaces between the plurality of quantum dots 50, and the second light-emitting layer 41 includes a plurality of quantum dots 50 and the second inorganic filler 53 filling the spaces between the plurality of quantum dots 50.

Note that filling the spaces between the plurality of quantum dots 50 with the inorganic filler 51 is required to be understood as filling at least a region K between a quantum dot 50A and a quantum dot 50B as illustrated in the schematic view 103 of a set P1 illustrated in FIG. 1. The region K is a region surrounded by two straight lines (common outer tangent lines) in contact with the outer circumferences of the quantum dot 50A and the quantum dot 50B and the outer circumferences of the quantum dot 50A and the quantum dot 50B facing each other in the cross-section of the light-emitting layer 24. Therefore, as illustrated in the schematic view 104 of the set P2 illustrated in FIG. 1, even if the quantum dot 50A and the quantum dot 50B are close to each other, the region K can exist, and the inorganic filler 51 fills the region K.

That the inorganic filler 51 fills the space between the plurality of quantum dots 50 does not necessarily mean that the region K between the quantum dot 50A and the quantum dot 50B is entirely composed only of the inorganic filler 51. For example, a material such as a ligand different from the material of the inorganic filler 51 may be included in the region K between the quantum dot 50A and the quantum dot 50B. Specifically, for example, the light-emitting layer 24 may contain an organic ligand that is added to improve the dispersibility of the quantum dots 50 in a solution used for coating formation and is coordinated with the outer circumferential surface of the quantum dots 50 in the solution. In this case, in the light-emitting layer 24, for example, the weight ratio of the organic ligand to the total weight including the region K may be less than 5% from the viewpoint of improving the reliability of the light-emitting layer 24.

The inorganic filler 51 may fill a region other than the plurality of quantum dots 50 in the light-emitting layer 24. For example, the outer edge (upper surface and lower surface) of the light-emitting layer 24 may be covered with the inorganic filler 51. Alternatively, a portion of the inorganic filler 51 may be located at the outer edges of the light-emitting layer 24, and the quantum dots 50 may be located away from the outer edges. The outer edges of the light-emitting layer 24 may not be formed only of the inorganic filler 51, and some of the quantum dots 50 may be exposed from the inorganic filler 51. The inorganic filler 51 may be indicated as a portion of the light-emitting layer 24 excluding the plurality of quantum dots 50.

The inorganic filler 51 may include the plurality of quantum dots 50. The inorganic filler 51 may be formed to fill the spaces formed between the plurality of quantum dots 50. The plurality of quantum dots 50 may be embedded in the inorganic filler 51 at intervals.

The inorganic filler 51 may include a continuous film having an area of 1000 nm² or more in a plane direction orthogonal to a film thickness direction. The continuous film may be a film that is not separated by a material other than a material constituting the continuous film in one plane. The continuous film may have an integrated film form seamlessly connected by chemical bondings of the inorganic filler 51.

The concentration of the inorganic filler 51 in the light-emitting layer 24 is, for example, the area ratio occupied by the inorganic filler 51 in a cross-section of the light-emitting layer 24. This concentration may be 10% or more and 90% or less, or 30% or more and 70% or less in the cross-sectional observation. This concentration is required be measured, for example, from an area ratio of an image obtained from the cross-sectional observation. When the quantum dots 50 have a structure with the core 50C and the shell 50S, the concentration of the shell 50S may be 1% or more and 50% or less. A total of ratios of the core 50C, the shell 50S, and the inorganic filler 51 may be adjusted to be 100% or less as appropriate.

In the light-emitting layer 24, the shell 50S as the outermost layer of each quantum dot 50 and the inorganic filler 51 may contain the same material. In this case, lattice mismatch on the interface between the shell 50S and the inorganic filler 51 is reduced, and defects such as dangling bonds at the interface are reduced. Therefore, the above configuration improves the efficiency in injection of carriers into the quantum dots 50. In addition, with the above-described configuration, deterioration in the effect of protecting the quantum dots 50 caused by defects at the interface can be curbed, deactivation of excitons in the quantum dots 50 can be reduced, and further the reliability of the light-emitting layer 24 and the luminous efficiency of the light-emitting element 11 can be improved.

In particular, the shell 50S as the outermost layer of each quantum dot 50 and the inorganic filler 51 may be made of the same material. In this case, the shell 50S as the outermost layer of the quantum dot 50 and the inorganic filler 51 may be distinguished from each other by recognizing a difference in crystallinity. For example, when there is a portion having the same composition but having a difference in crystallinity in cross-sectional observation of the light-emitting layer 24, the portion having higher crystallinity may be regarded as the shell 50S, and the other portion may be regarded as the inorganic filler 51. When the shell 50S cannot be distinguished from the inorganic filler 51, the shell 50S may be regarded as a part of the inorganic filler 51.

The light-emitting layer 24 may be composed of a plurality of the quantum dots 50 and the inorganic filler 51. The strength of carbon detected by the chain structure when the light-emitting layer 24 is analyzed may be equal to or less than noise level. In addition, the ratio of carbon detected from the light-emitting layer 24 may be 5% or less, 1% or less, or may not be detected. When the quantum dot 50 in which an organic ligand is coordinated is used in the light-emitting layer 24 as in the known art, the carbon chain of the organic ligand may be decomposed, the organic ligand itself may be detached from the quantum dot, or the like due to long-time driving. In this case, the quantum dots 50 may deteriorate to cause a decrease in luminance. As in the disclosure, by filling the spaces of the quantum dots 50 with the inorganic filler 51, the quantum dots 50 can be protected without using an organic ligand. Therefore, the display device 1 according to the present embodiment can achieve high reliability, in other words, can minimize a decrease in luminance caused by long-time driving of the light-emitting element 11.

The inorganic filler 51 contains at least one of a metal sulfide and a metal oxide. The metal sulfide may be, for example, zinc sulfide (ZnS), zinc magnesium sulfide (ZnₓMg₁₋ₓS (0<x<1), ZnMgS₂), gallium sulfide (GaS, Ga₂S₃), zinc tellurium sulfide (ZnₓTe₁₋ₓS (0<x<1)), magnesium sulfide (MgS), zinc gallium sulfide (ZnGa₂S₄), and magnesium gallium sulfide (MgGa₂S₄). The metal oxide may be zinc oxide (ZnO), titanium oxide (TiO₂), tin oxide (SnO₂), tungsten oxide (WO₃), and zirconium oxide (ZrO₂). It is desirable that the constituent material of the inorganic filler 51 have a wider band gap than the constituent material of the quantum dots 50 (for example, the material of the core 50C or the shell 50S).

Furthermore, the inorganic filler 51 may contain a chalcogenide containing a metal sulfide or a metal oxide. In other words, the inorganic filler 51 may contain a compound containing a group VI A (16) element.

The first inorganic filler 52 and the second inorganic filler 53 may be composed of an inorganic material having the same composition. Accordingly, lattice mismatch between the first inorganic filler 52 and the second inorganic filler 53 is reduced. Therefore, according to the above-described configuration, in the light-emitting element 11, defects such as dangling bonds at the boundary between the first light-emitting layer 40 and the second light-emitting layer 41 are reduced, and the reliability of the light-emitting layer 24 and the luminous efficiency of the light-emitting element 11 are further improved. Note that, in the disclosure, a material having the same composition does not mean that it is composed of exactly the same material, and it may have, for example, substitution or defects of no more than 5% of atoms.

Here, at each position at the substrate 20 in a plan view, a first plane connecting the quantum dots 50 positioned closest to the cathode 26 side in the first light-emitting layer 40 and a second plane connecting the quantum dots 50 positioned closest to the anode 21 side in the second light-emitting layer 41 are defined. When the first inorganic filler 52 and the second inorganic filler 53 are composed of an inorganic material having the same composition, the interface between the first light-emitting layer 40 and the second light-emitting layer 41 may be located between the first plane and the second plane. Furthermore, the light-emitting element 11 may include a layer including the first inorganic filler 52 and the second inorganic filler 53 but not including the quantum dots 50 between the first plane and the second plane.

In the present embodiment, the boundary between the light-emitting layer 24 and the electron transport layer 25 may be recognized by observing a cross-section passing through the light-emitting layer 24 and the electron transport layer 25 to confirm the concentration of sulfur atoms or oxygen atoms at each position on the cross-section. For example, in the cross-section, a portion in which the concentration of sulfur atoms or oxygen atoms is 25% or more may be regarded as the light-emitting layer 24, a portion in which the concentration of sulfur atoms or oxygen atoms is less than 25% may be regarded as the electron transport layer 25, and the boundary between the light-emitting layer 24 and the electron transport layer 25 may be confirmed. Alternatively, in the cross-section, a portion in which the concentration of sulfur atoms or oxygen atoms decreases by 25% or more may be regarded as the boundary between the light-emitting layer 24 and the electron transport layer 25. Note that when there are not only sulfur atoms and oxygen atoms but also atoms having a high concentration in only one of the light-emitting layer 24 and the electron transport layer 25, a portion in which the concentration of the aforementioned atoms changes by 25% or more may be regarded as the boundary between the light-emitting layer 24 and the electron transport layer 25. Therefore, as long as the above is satisfied, a portion at or near which the quantum dots 50 are not found may also be regarded as a part of the light-emitting layer 24. Note that, at the interface between the light-emitting layer 24 and the electron transport layer 25, the concentrations of sulfur atoms and oxygen atoms do not always change sharply. For this reason, the region of 1.2 nm or less on the anode 21 side from the interface determined above may be excluded from the light-emitting layer 24 or may be included in the electron transport layer 25.

### Study on Density of Free Electrons in Inorganic Filler

When the inorganic filler 51 contains a metal sulfide, the concentration of sulfur atoms in the first inorganic filler 52 is higher than the concentration of sulfur atoms in the second inorganic filler 53. In addition, when the inorganic filler 51 contains a metal oxide, the concentration of oxygen atoms in the first inorganic filler 52 is higher than the concentration of oxygen atoms in the second inorganic filler 53. Thus, in the inorganic filler 51, the concentration of at least one of sulfur atoms and oxygen atoms gradually decreases in the direction from the anode 21 toward the cathode 26. Note that, when the inorganic filler 51 contains a chalcogenide, the concentration of atoms of the chalcogen element contained in the chalcogenide decreases slowly or stepwisely in the direction from the anode 21 toward the cathode 26 in the inorganic filler 51.

In particular, when the inorganic filler 51 contains a metal sulfide, the density of atomic defects of sulfur atoms in the first inorganic filler 52 is lower than the density of atomic defects of sulfur atoms in the second inorganic filler 53. In addition, when the inorganic filler 51 contains a metal oxide, the density of atomic defects of oxygen atoms in the first inorganic filler 52 is lower than the density of atomic defects of oxygen atoms in the second inorganic filler 53. Thus, in the inorganic filler 51, the density of atomic defects of at least one of sulfur atoms and oxygen atoms gradually increases in the direction from the anode 21 toward the cathode 26. The difference in the concentration of sulfur atoms or oxygen atoms at each of positions in the inorganic filler 51 in the direction from the anode 21 toward the cathode 26 may correspond to the difference in the density of defects of the sulfur atoms or defects of the oxygen atoms of the inorganic filler 51 at each of the positions.

Note that, when the inorganic filler 51 contains a chalcogenide, the concentration of atomic defects of atoms of the chalcogen element contained in the chalcogenide increases slowly or stepwisely in the direction from the anode 21 toward the cathode 26 in the inorganic filler 51. In other words, in the inorganic filler (inorganic matrix material) 51, the concentration of atoms of the chalcogen element decreases slowly or stepwisely in the direction from the anode 21 toward the cathode 26. Hereinafter, in the disclosure, when the inorganic filler 51 contains a chalcogenide, the metal sulfide and the metal oxide of the inorganic filler 51 may be read as a chalcogenide, and the sulfur atoms and the oxygen atoms of the inorganic filler 51 may be read as atoms of a chalcogen element.

The concentration of sulfur atoms or oxygen atoms in the inorganic filler 51, in particular, the density of atomic defects of sulfur atoms or oxygen atoms, correlates with the density of free electrons at each position in the inorganic filler 51. This is because the concentration of free electrons contained in the inorganic filler 51 varies depending on the concentration of sulfur atoms or oxygen atoms in the inorganic filler 51. In particular, when a defect of sulfur atoms or oxygen atoms occurs in the inorganic filler 51 and the defect is activated, two free electrons per defect are generated near the defect.

Here, in order to study the density of free electrons on the hole transport layer 23 side in the light-emitting layer 24, the hole density at the interface between the hole transport layer 23 and the light-emitting layer 24 is studied. For example, when the hole transport layer 23 contains an organic material as a hole transport material, the current flowing through the hole transport layer 23 is a space-charge limiting current. For this reason, the hole density p in the vicinity of the interface between the hole transport layer 23 and the light-emitting layer 24 is expressed by the following equation.

$$p = \frac{1}{e} \sqrt{\frac{{ε}_{0} {ε}_{r} J}{2 L μ}} \qquad Equation 1$$

In the above equation, e represents an elementary charge amount, ε₀ represents a dielectric constant of vacuum, Er represents a relative dielectric constant of the hole transport layer 23, J represents a current density of the hole transport layer 23, L represents a film thickness of the hole transport layer 23, and u represents a hole mobility of the hole transport layer 23. Note that, in the disclosure, vicinity of the interface refers to the region within 1.2 nm from the interface in the film thickness direction.

For example, when the light-emitting element 11 is driven, a current density J of the current flowing through the hole transport layer 23 is set to 10 mA/cm². In addition, a relative dielectric constant Er of the hole transport layer 23 is set to 3.5, a thickness L is set to 30 nm, and a hole mobility u is set to 10⁻⁴ cm²/Vs. In this case, based on the above-described equation, the hole density p in the vicinity of the interface between the hole transport layer 23 and the light-emitting layer 24 is 1.4×10¹⁶ cm⁻³.

When free electrons are present in the vicinity of the interface between the hole transport layer 23 and the light-emitting layer 24, even when holes are injected from the hole transport layer 23 into the light-emitting layer 24, the holes may be recombined with free electrons outside the quantum dots 50 located in the vicinity of the interface and the light emission process may not be achieved. On the other hand, when the density of holes in the vicinity of the interface between the hole transport layer 23 and the light-emitting layer 24 exceeds the density of free electrons in the vicinity of the interface, excess holes are generated even when the electrons and the holes are recombined at the interface, and are easily injected into the quantum dots 50. Thus, from the viewpoint of improving the efficiency in injection of holes from the hole transport layer 23 to the light-emitting layer 24, the density of holes in the vicinity of the interface between the hole transport layer 23 and the light-emitting layer 24 is required to be higher than the density of free electrons in the vicinity of the interface.

Therefore, in order to improve the efficiency in injection of holes from the hole transport layer 23 into the light-emitting layer 24, the density of free electrons in the inorganic filler 51 may be 1×10¹⁶ cm⁻³ or less in the region within 1.2 nm in the film thickness direction from the end face of the light-emitting layer 24 on the anode 21 side. In other words, in the region within 1.2 nm in the film thickness direction of the first light-emitting layer 40 from the interface between the hole transport layer 23 and the first light-emitting layer 40, the density of free electrons of the first inorganic filler 52 in the first light-emitting layer 40 may be 1×10¹⁶ cm⁻³ or less.

Here, when the inorganic filler 51 has a polycrystalline or amorphous structure, it is considered that the activation percentage of the inorganic filler 51 is not high and is about 1%. Therefore, the activation percentage of the inorganic filler 51 in the light-emitting layer 24 is set to 1%, in other words, one out of 100 defects of sulfur atoms or oxygen atoms in the inorganic filler 51 is assumed to be activated, and two free electrons are assumed to be generated. In this case, the defect density of sulfur atoms or oxygen atoms in the inorganic filler 51 may be 5×10¹⁷ cm⁻³ or less in the region within 1.2 nm in the film thickness direction from the end face of the light-emitting layer 24 on the anode 21 side. With the above-described configuration, the density of free electrons in the inorganic filler 51 in the region can be 1×10¹⁶ cm⁻³ or less, and the efficiency in injection of holes from the hole transport layer 23 to the light-emitting layer 24 can be improved. In addition, since the density of free electrons in the inorganic filler 51 is low, the resistivity of the inorganic filler 51 increases. Thus, a reactive current that does not contribute to light emission due to carriers flowing through the inorganic filler 51 and being not injected into the quantum dots 50 is reduced. As a result, the above-described configuration improves the luminous efficiency of the light-emitting element 11.

A proportion of defects of sulfur atoms or oxygen atoms in the inorganic filler 51 in the above case will be studied. If the inorganic filler 51 is composed of zinc sulfide (ZnS), the lattice constant of sulfur sulfide is about 5.87 Å, and four sulfur atoms are contained per lattice. For this reason, in the above case, the proportion of defects of sulfur atoms to zinc atoms in the inorganic filler 51 is 5×10¹⁷ cm⁻³×(5.87 Å) 3/4, which is about 2.5×10⁻³%.

Next, the density of free electrons in the light-emitting layer 24 on the electron transport layer 25 side will be studied. When free electrons are present in the vicinity of the interface between the electron transport layer 25 and the light-emitting layer 24, the free electrons move in the light-emitting layer 24 to the anode 21 side when the light-emitting element 11 is driven. Therefore, when the density of free electrons in the light-emitting layer 24 on the electron transport layer 25 side is high, the proportion of free electrons injected into the quantum dots 50 and flowing between the quantum dots 50 increases. In addition, when the density of the atomic defects of the inorganic filler 51 in the light-emitting layer 24 is high, the electron mobility in the light-emitting layer 24 may decrease, and further the electron transport ability of the light-emitting layer 24 may decrease.

On the other hand, when the density of free electrons in the vicinity of the interface between the electron transport layer 25 and the light-emitting layer 24 is low, the concentration of electrons injected from the electron transport layer 25 decreases, and there is a possibility that an excess of holes in the light-emitting layer 24 is caused.

Therefore, the density of free electrons in the vicinity of the interface between the electron transport layer 25 and the light-emitting layer 24 is required to be within a predetermined range from the viewpoint of improving the efficiency in electron injection from the electron transport layer 25 to the light-emitting layer 24 while preventing electrons from flowing between the quantum dots 50.

In order to improve the efficiency in electron injection from the electron transport layer 25 to the light-emitting layer 24, the density of free electrons of the light-emitting layer 24 in the vicinity of the interface between the light-emitting layer 24 and the electron transport layer 25 is preferably equal to or higher than the density of free electrons in the electron transport layer 25. For example, when the nanoparticles 30 of the electron transport layer 25 are zinc oxide-based nanoparticles, the density of free electrons in the electron transport layer 25 is about 1×10¹⁸ cm⁻³. Therefore, in order to improve the efficiency in injection of electrons from the electron transport layer 25 into the light-emitting layer 24, the density of free electrons in the inorganic filler 51 may be 1×10¹⁸ cm⁻³ or more in the region within 1.2 nm in the film thickness direction from the end face of the light-emitting layer 24 on the cathode 26 side. In other words, in the region within 1.2 nm in the film thickness direction of the second light-emitting layer 41 from the interface between the electron transport layer 25 and the second light-emitting layer 41, the density of free electrons of the second inorganic filler 53 in the second light-emitting layer 41 may be 1×10¹⁸ cm⁻³ or more.

Here, as described above, the activation percentage of the inorganic filler 51 in the light-emitting layer 24 is set to 1%. In this case, the defect density of sulfur atoms or oxygen atoms in the inorganic filler 51 may be 5×10¹⁹ cm⁻³ or more in the region within 1.2 nm in the film thickness direction from the end face of the light-emitting layer 24 on the cathode 26 side. With the above-described configuration, the density of free electrons in the inorganic filler 51 in the region can be 1×10¹⁸ cm⁻³ or more, and the efficiency in injection of electrons from the electron transport layer 25 to the light-emitting layer 24 can be improved.

On the other hand, in order to reduce a decrease in the electron transport ability of the light-emitting layer 24, the atomic defects of the inorganic filler 51 of the light-emitting layer 24 in the vicinity of the interface between the electron transport layer 25 and the light-emitting layer 24 may be about 10% or less. When the inorganic filler 51 is composed of zinc sulfide (ZnS), the value obtained by multiplying the density of atomic defects by (5.87 Å) ¾ may be 0.1 or less in order to reduce the atomic defects of the inorganic filler 51 to 10% or less. The density of atomic defects satisfying the above conditions is 0.1×4/(5.87 Å) 3 or less, and about 2×10²¹ cm⁻³ or less.

Therefore, in order to reduce a decrease in the electron transport ability of the light-emitting layer 24 and improve the efficiency in injection of electrons from the electron transport layer 25 into the light-emitting layer 24, the defect density of sulfur atoms or oxygen atoms in the inorganic filler 51 may be 2×10²¹ cm⁻³ or less in the region within 1.2 nm in the film thickness direction from the end face of the light-emitting layer 24 on the cathode 26 side. In other words, in the region within 1.2 nm in the film thickness direction of the second light-emitting layer 41 from the interface between the electron transport layer 25 and the second light-emitting layer 41, the defect density of sulfur atoms or oxygen atoms of the second inorganic filler 53 in the second light-emitting layer 41 may be 2× 10²¹ cm⁻³ or less.

As described above, the activation percentage of the inorganic filler 51 in the light-emitting layer 24 is set to 1%. In this case, the density of free electrons in the inorganic filler 51 may be 4×10¹⁹ cm⁻³ or less in the region within 1.2 nm in the film thickness direction from the end face of the light-emitting layer 24 on the cathode 26 side. With the above configuration, the defect density of sulfur atoms or oxygen atoms in the inorganic filler 51 in the region can be 2×10²¹ cm⁻³ or less, and a decrease in the electron transport ability of the light-emitting layer 24 can be reduced.

Note that the density of free electrons of the inorganic fillers 51 in the region within 1.2 nm in the film thickness direction from the end face of the light-emitting layer 24 on the anode 21 side may be one tenth or less of the density of free electrons thereof in the region within 1.2 nm in the film thickness direction from the end face of the light-emitting layer 24 on the cathode 26 side. In other words, the density of free electrons of the first inorganic filler 52 of the first light-emitting layer 40 may be one tenth or less of the density of free electrons of the second inorganic filler 53 of the second light-emitting layer 41. In this case, since both the efficiency in hole injection and the efficiency in electron injection into the light-emitting layer 24 can be improved, the drive voltage of the light-emitting element 11 can be reduced, and the energy efficiency of the light-emitting layer 24 can be improved. Furthermore, carrier balance in the light-emitting layer 24 can be adjusted, and the luminous efficiency of the light-emitting element 11 is improved.

### Light-Emitting Element: Method for Manufacturing

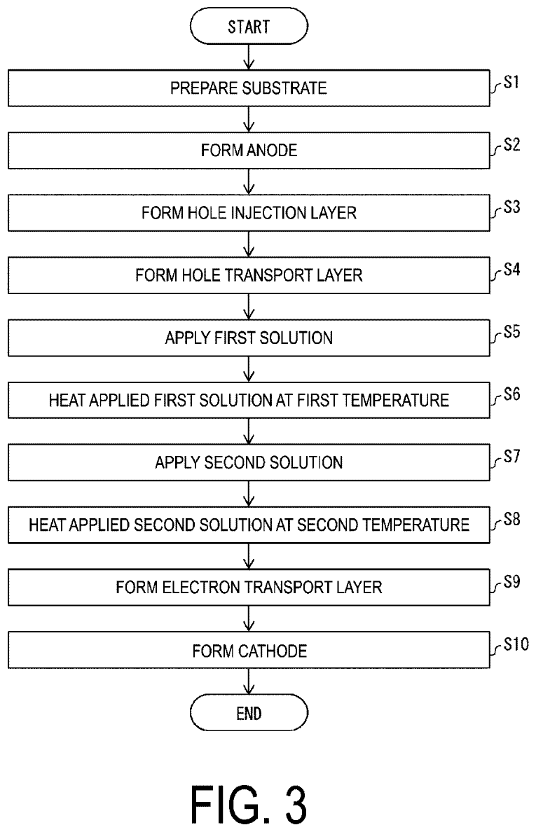

The method for manufacturing the light-emitting element 11 according to the present embodiment will be described with reference to FIG. 3. FIG. 3 is a flowchart showing a method for manufacturing the light-emitting element 11 according to the present embodiment.

In the method for manufacturing the light-emitting element 11 according to the present embodiment, first, the substrate 20 is prepared as shown in FIG. 3 (step S₁). The substrate 20 may be a substrate in which a pixel circuit is formed for each subpixel on a glass substrate, a film substrate, or the like. A driver in the frame portion NA, wiring between the driver and each pixel circuit, and the like may be formed on the substrate 20.

Next, the anode 21 is formed on the substrate 20 (step S₂). The anode 21 may be formed by depositing a thin metal film using a sputtering method or the like on the substrate 20. The anode 21 may be formed to be electrically connected to the pixel circuit, or may be patterned for each subpixel. For example, the anode 21 may be formed by forming an ITO film having a thickness of 30 nm on the substrate 20 by using a sputtering method.

Next, the hole injection layer 22 is formed on the anode 21 (step S₃). In step S₃, for example, a solution obtained by dispersing nickel oxide nanoparticles at 15 mg/mL in a solvent in which water and 2-methoxyethanol have been mixed in equal volumes may be applied onto the anode 21 by using a spin coating method and baked at 200° C. This process may be performed only once, or may be repeated as many as two to five times. Next, a solution in which MeO-2PACz has been dispersed in an ethanol solvent may be applied to the nickel oxide nanoparticle layer by using the spin coating method in a nitrogen atmosphere, and then the solvent may be volatilized by baking. Thus, a layered structure of the nickel oxide nanoparticle layer and a self-assembled monolayer of MeO-2PACz may be formed to form the hole injection layer 22.

Next, the hole transport layer 23 is formed on the hole injection layer 22 (step S4). In step S4, a solution in which poly-TPD is dispersed in a chlorobenzene solvent may be applied to the self-assembled monolayer by using the spin coating method in a nitrogen atmosphere, and then the solvent may be volatilized by baking. Thus, a poly-TPD film having a thickness of 30 nm may be formed on the self-assembled monolayer to form the hole transport layer 23. In step S3, a TFB film or a PVK film may be formed instead of the poly-TPD film.

Next, the light-emitting layer 24 is formed on the hole transport layer 23. In the present embodiment, an example in which the light-emitting layer 24 is formed by forming the first light-emitting layer 40 and then forming the second light-emitting layer 41 on the first light-emitting layer 40 will be described.

In the step of forming the light-emitting layer 24 according to the present embodiment, first, a first solution synthesized in advance in a separate step is applied onto the hole transport layer 23 by using a spin coating method or the like (step S5). The first solution is a mixed solution containing a plurality of quantum dots 50 and a first inorganic precursor which is a precursor of the first inorganic filler 52. The first inorganic precursor contains a metal source of the first inorganic filler 52 and a sulfur source or an oxygen source.

Next, the first solution applied onto the hole transport layer 23 is heated at a first temperature (step S6). For example, the first temperature may be 150° C. In detail, in step S6, the first solution applied onto the hole transport layer 23 may be heated for 30 minutes under an atmosphere of 150° C.

Thereby, the solvent of the first solution is volatilized, the first inorganic precursor in the first solution is denatured, and the first inorganic filler 52 is formed. Here, the first inorganic precursor in the first solution is denatured by heating in step S6, and the first inorganic fillers 52 are sequentially formed around the quantum dots 50 contained in the first solution. Thus, in step S6, the first inorganic filler 52 is formed to fill the spaces between a plurality of quantum dots 50. As described above, the first light-emitting layer 40 including the plurality of quantum dots 50 and the first inorganic filler 52 filling the spaces between the quantum dots 50 is formed.

Next, a second solution synthesized in advance in another step is applied onto the first light-emitting layer 40 by using a spin coating method or the like (step S7). The second solution is a mixed solution containing a plurality of quantum dots 50 and a second inorganic precursor which is a precursor of the second inorganic filler 53. The second inorganic precursor contains a metal source and a sulfur source or an oxygen source of the second inorganic filler 53. Note that, in the disclosure, the precursors, that is, the first inorganic precursor and the second inorganic precursor, may contain, for example, a zinc source containing zinc carboxylate or the like, a magnesium source containing magnesium carboxylate or the like, a selenium source containing selenourea or the like, or a sulfur source containing thiourea or the like. In addition, the precursors may include, for example, at least one kind of a metal acetate, a metal nitrate, or a metal halide as a metal source, and thiourea, N-methylthiourea, 1,3-dimethylthiourea, N,N′-dimethylthiourea, tetramethylthiourea, or thioacetamide as a sulfur source. Alternatively, the precursor 36 may contain a metal complex in which thiourea, N-methylthiourea, 1,3-dimethylthiourea, N,N′-dimethylthiourea, tetramethylthiourea, or thioacetamide is coordinated with metal atoms.

Note that the concentration of the quantum dots 50 with respect to the concentration of the second inorganic precursor in the second solution is lower than the concentration of the quantum dots 50 with respect to the concentration of the first inorganic precursor in the first solution. As a result, the concentration of the quantum dots 50 in the second light-emitting layer 41 formed by a method described below can be made lower than that of the quantum dots 50 in the first light-emitting layer 40 while the application amount of the second solution in step S8 is set to be substantially equal to the application amount of the first solution in step S6.

Next, the second solution applied onto the first light-emitting layer 40 is heated at a second temperature higher than the first temperature (step S8). For example, the second temperature may be 200° C. In detail, in step S8, the second solution applied onto the first light-emitting layer 40 may be heated for 30 minutes under an atmosphere of 200° C.

Thereby, the solvent of the second solution is volatilized, the second inorganic precursor in the second solution is denatured, and the second inorganic filler 53 is formed. As described above, the second light-emitting layer 41 including the plurality of quantum dots 50 and the second inorganic filler 53 filling the spaces between the quantum dots 50 is formed, similarly to the first light-emitting layer 40.

Note that, both step S6 and step S8 include a step of heating a solution containing the precursor containing a metal source and a sulfur source or an oxygen source of the inorganic filler 51. Here, by heating the solution, the sulfur source or the oxygen source contained in the precursor in the solution may be volatilized together with the solvent. In addition, the amount of the sulfur source or the oxygen source volatilized tends to increase as the heating temperature of the solution gets higher.

Here, the heating temperature of the second solution in step S8 is the second temperature, which is higher than the first temperature that is the heating temperature of the first solution in step S6. For this reason, the proportion of the sulfur source or the oxygen source volatilized from the second solution in step S8 is higher than the proportion of the sulfur source or the oxygen source volatilized from the first solution in step S6.

In addition, both the first solution and the second solution heated in step S6 and step S8 contain the quantum dots 50. For this reason, in order to improve the dispersibility of the quantum dots 50 in the first solution and the second solution, xanthogenic acid may be added to both solutions as a ligand capable of coordinating with the quantum dots 50.

Here, as described above, the concentration of the quantum dots 50 in the second solution is lower than the concentration of the quantum dots 50 in the first solution. For this reason, when xanthogenic acid is added to the first solution and the second solution, the proportion of the xanthogenic acid coordinating with the quantum dots 50 in the second solution is lower than the proportion of the xanthogenic acid coordinating with the quantum dots 50 in the first solution.

Since coordination bonds are not formed among quantum dots 50 in xanthogenic acid not coordinating with quantum dots 50, the attractive force between the quantum dots 50 is weak. For this reason, the percentage of sulfur atoms of the xanthogenic acid not coordinating with the quantum dots 50 being volatilized together with the solvent by heating is higher than the percentage of sulfur atoms of the xanthogenic acid coordinating with the quantum dots 50.

Thus, the concentration of sulfur atoms derived from the xanthogenic acid remaining in the second light-emitting layer 41 is lower than the concentration of sulfur atoms derived from the xanthogenic acid remaining in the first light-emitting layer 40. Therefore, the density of atomic defects of sulfur atoms in the second inorganic filler 53 of the second light-emitting layer 41 is higher than the density of atomic defects of sulfur atoms in the first inorganic filler 52 of the first light-emitting layer 40.

As described above, the density of atomic defects of sulfur atoms or oxygen atoms in the second inorganic filler 53 formed in step S8 is higher than the density of atomic defects of sulfur atoms or oxygen atoms in the first inorganic filler 52 formed in step S6. Therefore, in the above-described step, the light-emitting layer 24 including the inorganic filler 51 in which the density of atomic defects of at least one of sulfur atoms and oxygen atoms gradually increases in the direction from the anode 21 to the cathode 26 is formed. In other words, in the above-described step, the light-emitting layer 24 including the inorganic filler 51 in which the concentration of at least one of sulfur atoms and oxygen atoms gradually decreases in the direction from the anode 21 to the cathode 26 is formed.

Following the formation of the light-emitting layer 24, the electron transport layer 25 is formed on the light-emitting layer 24 (step S9). In step S9, the electron transport layer 25 having a film thickness of 60 nm may be formed by applying a solution in which zinc-oxide nanoparticles 30 have been dispersed in an ethanol solvent onto the light-emitting layer 24 by using a spin coating method or the like under a nitrogen atmosphere and drying the solution. The zinc oxide nanoparticles 30 may be doped with at least one kind of Li, Mg, Al, Ti, Ga, and Zr. In addition, the nanoparticles 30 may also be nanoparticles of titanium oxide or zirconium oxide.

Next, the cathode 26 is formed on the electron transport layer 25 (step S10). In step S10, the cathode 26 may be formed by forming a silver thin film having a film thickness of 50 nm through vacuum vapor deposition. In this way, the light-emitting element 11 is manufactured. The manufacturing of the display device 1 may be completed with the completion of the manufacturing of the light-emitting element 11 described above, or a sealing layer or the like for sealing or protecting the light-emitting element 11 may be formed subsequently to the manufacturing of the light-emitting element 11.

### Effects of Light-Emitting Element

The light-emitting element 11 includes the light-emitting layer 24 having a plurality of quantum dots 50 and the inorganic filler 51 filling the spaces between the plurality of quantum dots 50. The inorganic filler 51 contains at least one of a metal sulfide and a metal oxide, and the concentration of at least one of sulfur atoms and oxygen atoms thereof gradually decreases in the direction from the anode 21 toward the cathode 26. Particularly, in the inorganic filler 51, the density of defects of at least one of sulfur atoms and oxygen atoms gradually increases in the direction from the anode 21 toward the cathode 26.

For this reason, in the inorganic filler 51, the density of free electrons increases in the direction from the anode 21 toward the cathode 26. Thus, in the light-emitting element 11, since both the efficiency in hole injection and the efficiency in electron injection into the light-emitting layer 24 can be improved based on the reason described above, the drive voltage of the light-emitting element 11 can be reduced, and the energy efficiency of the light-emitting layer 24 can be improved. Furthermore, carrier balance in the light-emitting layer 24 can be adjusted, and the luminous efficiency of the light-emitting element 11 is improved.

The concentration of the quantum dots 50 in the second light-emitting layer 41 is lower than the concentration of the quantum dots 50 in the first light-emitting layer 40. For this reason, in the light-emitting layer 24, the concentration of the quantum dots 50 gradually decreases in the direction from the anode 21 toward the cathode 26.

Since the mobility of electrons in a semiconductor is generally higher than the mobility of holes, in the light-emitting layer 24 containing the quantum dots 50, light emission is mainly obtained from the quantum dots 50 located on the anode 21 side. For this reason, with the above-described configuration, since the density of free electrons in the first inorganic filler 52 on the anode 21 side is small, the resistance becomes large in the light-emitting layer 24. Thus, the light-emitting layer 24 can reduce a reactive current that does not contribute to light emission and is generated when carriers flow through the first inorganic filler 52 without entering the quantum dots 50. Thus, with the above-described configuration, the light-emitting element 11 can obtain light emission from the quantum dots 50 more efficiently. In addition, defects of the inorganic filler 52 are more likely to be generated on the surface than the inside. Therefore, in the above-described configuration, the average distance between a defect and a quantum dot 50 can be increased, and thus deactivation of excitons caused by the defect can be curbed, and the luminous efficiency of the light-emitting element 11 can be improved.

In addition, when the second light-emitting layer 41 is compared with the first light-emitting layer 40, the thickness of the inorganic filler 51 filling the spaces between the quantum dots 50 can be effectively increased therein, and thereby the effect of the inorganic filler 51 protecting the quantum dots 50 can be enhanced. For this reason, in the light-emitting element 11, the light-emitting layer 24 can be more efficiently protected from foreign matters such as moisture and oxygen infiltrating from the cathode 26 side, heat propagating from the cathode 26 side, or the like.

In particular, the light-emitting element 11 according to the present embodiment includes the anode 21 on the substrate 20 side. In general, infiltration of foreign matters such as moisture is less likely to progress in the substrate 20 than in each layer between the electrodes of the light-emitting element 11. Therefore, foreign matters easily infiltrate into the light-emitting element 11 from the cathode 26 side, which is the side opposite to the substrate 20 side. Furthermore, since the electron transport layer 25 located closer to the cathode 26 than the light-emitting layer 24 includes the nanoparticles 30, foreign matters infiltrated into the light-emitting element 11 from the cathode 26 side easily reach the light-emitting layer 24 through the nanoparticles 30. Therefore, in the light-emitting element 11 having the above-described configuration, the effect of the inorganic filler 51 of the light-emitting layer 24 protecting the quantum dots 50 can be more efficiently enhanced. The substrate 20 is preferably a glass substrate because infiltration of foreign matters such as moisture is less likely to progress in a glass substrate than in a film substrate.

The inorganic filler 51 may include a binary compound semiconductor. In this case, the difference in density of the atomic defects of sulfur atoms or oxygen atoms at each position in the inorganic filler 51 can be easily realized by the difference in the heating temperatures in the above-described step S6 and step S8. In particular, the inorganic filler 51 may contain zinc sulfide from the viewpoint of enhancing the effect of protecting the quantum dots 50 and enhancing the efficiency in injection of carriers into the quantum dots 50.

### Second Embodiment

### Inorganic Filler Layer

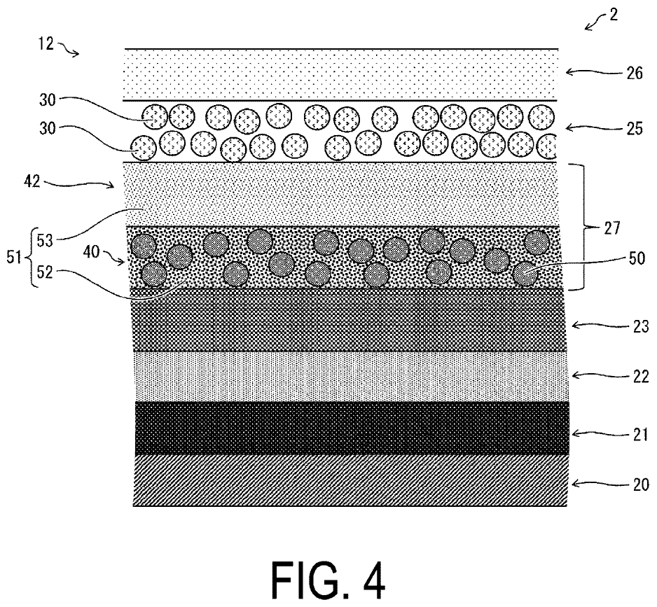

A display device 2 according to the present embodiment will be described with reference to FIG. 4. FIG. 4 is a schematic side cross-sectional view of the display device 2 according to the present embodiment. The display device 2 according to the present embodiment has the same configuration as that of the display device 1 according to the above embodiment except that a light-emitting element 12 is provided in place of the light-emitting element 11. The light-emitting element layer 12 has the same configuration as the light-emitting element 11 according to the above embodiment except that a light-emitting layer 27 is provided instead of the light-emitting layer 24.

The light-emitting layer 27 includes a first light-emitting layer 40 and a second light-emitting layer 42 in this order from the anode 21 side. The first light-emitting layer 40 according to the present embodiment has the same configuration as the first light-emitting layer 40 according to the above embodiment. The second light-emitting layer 42 according to the present embodiment has a different configuration from the second light-emitting layer 41 according to the above embodiment in that the former includes just the second inorganic filler 53 and includes no quantum dots 50.

In other words, the light-emitting layer 27 includes the first light-emitting layer 40 as a quantum dot layer containing quantum dots 50 and a first inorganic filler 52 as the inorganic filler 51. In addition, the light-emitting layer 27 includes the second light-emitting layer 42 as an inorganic filler layer containing the second inorganic filler 53 as the inorganic filler 51. Here, the second light-emitting layer 42 includes only the inorganic filler 51 from among the quantum dots 50 and the inorganic filler 51. As long as this configuration is satisfied, the second light-emitting layer 42 may contain a material different from the quantum dots 50 and the inorganic filler 51.

Therefore, also in the present embodiment, the light-emitting layer 27 contains a plurality of quantum dots 50, and includes the first inorganic filler 52 and the second inorganic filler 53 as the inorganic filler 51 in order from the anode 21 side. Thus, also in the present embodiment, the inorganic filler 51 contains at least one of a metal sulfide and a metal oxide, and the concentration of at least one of sulfur atoms and oxygen atoms gradually decreases in the direction from the anode 21 toward the cathode 26. Particularly, in the inorganic filler 51, the density of defects of at least one of sulfur atoms and oxygen atoms gradually increases in the direction from the anode 21 toward the cathode 26.

With the above-described configuration, the light-emitting element 12 prevents electrons injected from the electron transport layer 25 from moving between the quantum dots 50 in the light-emitting layer 27 for the same reason as that described for the light-emitting element 11. Therefore, the light-emitting element 12 reduces the reactive current in the light-emitting layer 27 and improves the luminous efficiency and reliability.

In particular, in the present embodiment, the light-emitting layer 27 of the light-emitting element 12 includes the second light-emitting layer 42 not containing quantum dots 50. For this reason, the light-emitting layer 27 has no quantum dots 50, which may deteriorate due to foreign matters or the like from the cathode 26 side, in the second light-emitting layer 42 on the cathode 26 side. In addition, since the second light-emitting layer 42 contains no quantum dots 50, the effective film thickness of the second inorganic filler 53 is increased and the effect of protection by the light-emitting layer 27 is increased. In addition, the light-emitting layer 27 efficiently transports electrons having higher mobility than holes from the second light-emitting layer 42 to the first light-emitting layer 40, and light emission from the quantum dots 50 of the first light-emitting layer 40 can be obtained. Therefore, the light-emitting element 12 can improve the luminous efficiency while more efficiently enhancing the effect of the inorganic filler 51 of the light-emitting layer 27 protecting the quantum dots 50. Note that the film thickness of the second light-emitting layer 42 may be 1.2 nm or more, or may be 6 nm or more. Thus, since the second light-emitting layer 42 has a film thickness approximately twice or more the unit lattice of the second inorganic filler, the protection effect of the light-emitting layer 27 can be efficiently enhanced.

When the film thickness of the second light-emitting layer 42 is large, there is a possibility that the drive voltage of the light-emitting element 12 increases. For that reason, in the present embodiment, the density of free electrons in the inorganic filler 51 may be 1×10¹⁸ cm⁻³ or more in the region within 1.2 nm in the film thickness direction from the end face of the light-emitting layer 27 on the cathode 26 side. Since the above-described configuration can sufficiently increase the density of free electrons in the region, it is preferable in the light-emitting layer 27 to reduce the resistivity of the inorganic filler 51 in the region and increase the effect of protecting the quantum dots 50 while an increase in the drive voltage of the light-emitting element 12 is minimized.

In the present embodiment as well, the boundary between the light-emitting layer 27 and the electron transport layer 25 may be recognized by observing a cross-section passing through the light-emitting layer 27 and the electron transport layer 25 to confirm the composition of the materials at each position on the cross-section. In the present embodiment, for example, a portion where the concentration of atoms of at least one kind contained in the second inorganic filler 53 is 25% or lower may be regarded as the boundary between the light-emitting layer 27 and the electron transport layer 25. Alternatively, a portion where the concentration of atoms of at least one kind contained in the second inorganic filler 53 decreases by 25% or more may be regarded as the boundary between the light-emitting layer 27 and the electron transport layer 25. Note that, when there are atoms having a higher concentration in only one of the second inorganic filler 53 and the electron transport layer 25, a portion where the concentration of the atoms changes by 25% or more may be regarded as the boundary between the light-emitting layer 27 and the electron transport layer 25. The criteria for identifying the boundary have priority in the order as described above, in other words, the criterion described first has priority over that described later.

In other words, even when the light-emitting layer 27 has a portion containing no quantum dots 50, like the second light-emitting layer 42, a portion where the composition of the second inorganic filler 53 can be found may be regarded as being included in the second light-emitting layer 42, and further regarded as being included in the light-emitting layer 27.

The light-emitting element 12 according to the present embodiment may be manufactured by using the same method as the method for manufacturing the light-emitting element 11 according to the above embodiment as described in the flowchart shown in FIG. 3, except for the material of the second solution applied onto the first light-emitting layer 40 in step S7. In the present embodiment, the second solution contains only the second inorganic precursor from among the quantum dots 50 and the second inorganic precursor which is a precursor of the second inorganic filler 53. For example, the second solution may contain materials other than the quantum dots 50 and the second inorganic precursor. Thus, in step S8, the second light-emitting layer 42 not including quantum dots 50 but including the second inorganic filler 53 is formed on the first light-emitting layer 40.

### Third Embodiment

### Plurality of Quantum Dot Layers

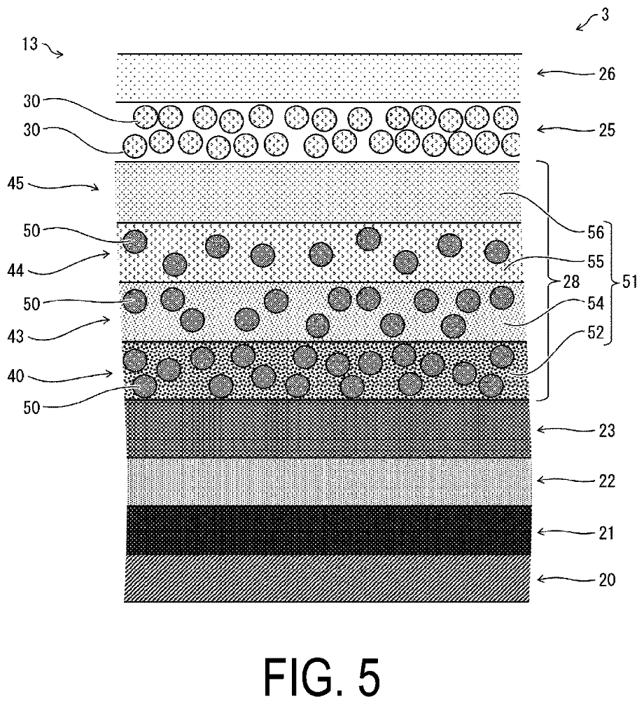

A display device 3 according to the present embodiment will be described with reference to FIG. 5. FIG. 5 is a schematic side cross-sectional view of the display device 3 according to the present embodiment. The display device 3 according to the present embodiment has the same configuration as that of the display device 2 according to the above embodiment except that a light-emitting element 13 is provided in place of the light-emitting element 12. The light-emitting element 13 has the same configuration as the light-emitting element 12 according to the above embodiment except that a light-emitting layer 28 is provided instead of the light-emitting layer 27.

The light-emitting layer 28 includes, in order from the anode 21 side, a first light-emitting layer 40, a second light-emitting layer 43, a third light-emitting layer 44, and a fourth light-emitting layer 45. The first light-emitting layer 40 has the same configuration as the first light-emitting layer 40 according to each of the above-described embodiments. The second light-emitting layer 43 includes a plurality of quantum dots 50 and a second inorganic filler 54 filling the spaces between the plurality of quantum dots 50. The third light-emitting layer 44 includes a plurality of quantum dots 50 and a third inorganic filler 55 filling the spaces between the plurality of quantum dots 50. The fourth light-emitting layer 45 has the same configuration as the second light-emitting layer 42 according to the above embodiment except that the fourth light-emitting layer 45 includes a fourth inorganic filler 56 instead of the second inorganic filler 53.

The quantum dots 50 included in the second light-emitting layer 43 and the third light-emitting layer 44 have the same configuration as that of the quantum dots 50 according to each of the embodiments described above. In addition, the second inorganic filler 54, the third inorganic filler 55, and the fourth inorganic filler 56 have the same configuration as that of the first inorganic filler 52 according to each of the above-described embodiments except for the concentration of at least one of sulfur atoms and oxygen atoms.

Therefore, the light-emitting layer 28 includes the quantum dots 50 and the first inorganic filler 52, the second inorganic filler 54, the third inorganic filler 55, and the fourth inorganic filler 56 as the inorganic filler 51. In particular, the light-emitting layer 28 includes a first light-emitting layer 40, a second light-emitting layer 43, and a third light-emitting layer 44 as quantum dot layers including quantum dots 50 and an inorganic filler 51. In addition, the light-emitting layer 28 includes the fourth light-emitting layer 45 including only the inorganic filler 51 from among the quantum dots 50 and the inorganic filler 51.

In the present embodiment, the concentration of at least one of sulfur atoms and oxygen atoms gradually decreases in the first inorganic filler 52, the second inorganic filler 54, the third inorganic filler 55, and the fourth inorganic filler 56 in this order. In other words, also in the present embodiment, the concentration of at least one of sulfur atoms and oxygen atoms gradually decreases in the inorganic filler 51 in the direction from the anode 21 toward the cathode 26.

In particular, the density of atomic defects of at least one of sulfur atoms and oxygen atoms gradually increases in the first inorganic filler 52, the second inorganic filler 54, the third inorganic filler 55, and the fourth inorganic filler 56 in this order. In other words, also in the present embodiment, the density of atomic defects of at least one of sulfur atoms and oxygen atoms gradually increases in the inorganic filler 51 in the direction from the anode 21 toward the cathode 26.

As described above, for the same reason as that described in each of the above-described embodiments, in the light-emitting element 13 according to the present embodiment, electrons injected from the electron transport layer 25 into the light-emitting layer 28 are prevented from moving between the quantum dots 50. Therefore, in the light-emitting element 13, a reactive current in the light-emitting layer 28 is reduced and the luminous efficiency and reliability are enhanced.

The concentration of the quantum dots 50 in the light-emitting layer 28 decreases in the order of the first light-emitting layer 40, the second light-emitting layer 43, and the third light-emitting layer 44. Furthermore, the fourth light-emitting layer 45 contains no quantum dots 50 as described above. Therefore, the light-emitting element 13 can improve the luminous efficiency while more efficiently enhancing the effect of the inorganic filler 51 of the light-emitting layer 28 protecting the quantum dots 50 for the same reason as that described in each of the above-described embodiments.

In particular, in the light-emitting element 13 according to the present embodiment, even when the efficiency in injection of holes into the light-emitting layer 28 caused by deterioration of each part is reduced, a decrease in the luminous efficiency can be reduced. For example, it is assumed in the light-emitting element 13 that recombination of electrons and holes in the light-emitting layer 28 occurs in the quantum dots 50 near the second light-emitting layer 43 and mainly the quantum dots 50 of the second light-emitting layer 43 emit light at the time of shipment of the display device 3. In this case, the mobility and the injection efficiency of holes from the hole injection layer 22 to the light-emitting layer 28 may be reduced as deterioration of each part of the light-emitting element 13 due to deterioration caused by driving of the display device 3 or deterioration over time. This is because the durability of the hole injection layer 22 or the hole transport layer 23 is generally inferior to the durability of the electron transport layer 25. This is particularly remarkable when an organic material is used for the hole transport layer 23 and an inorganic material is used for the electron transport layer 25. This may cause recombination of electrons and holes in the light-emitting layer 28 to occur in the quantum dots 50 closer to the anode 21 than the second light-emitting layer 43. Also in this case, recombination of electrons and holes in the light-emitting layer 28 occurs in the quantum dots 50 in the vicinity of the first light-emitting layer 40, and mainly the quantum dots 50 in the first light-emitting layer 40 can emit light, and thus the light-emitting element 13 can reduce deterioration of the luminous efficiency. In other words, even when the hole injection into the light-emitting layer 28 is deteriorated due to the deterioration of each layer of the light-emitting element 13, the decrease in the luminous efficiency of the light-emitting element 13 caused by the deterioration of carrier balance in the light-emitting layer 28 can be curbed only by shifting the light-emitting position to the anode 21 side. Thus, the light-emitting layer 28 can improve the reliability of the light-emitting element 13.

The method for manufacturing the light-emitting element 13 according to the present embodiment is the same method as the method for manufacturing the light-emitting element 12 according to the above embodiment except for the method for forming the light-emitting layer 28. In the present embodiment, the first light-emitting layer 40, the second light-emitting layer 43, and the third light-emitting layer 44 in the light-emitting layer 28 may be formed by repeatedly performing the above-described steps S5 and S6.

However, in the present embodiment, the concentration of the quantum dots 50 in the solution applied in step S5 is gradually decreased, the heating temperature of the solution in step S6 is gradually increased, and step S5 and step S6 are repeatedly performed. Accordingly, the first light-emitting layer 40, the second light-emitting layer 43, and the third light-emitting layer 44 described above can be formed. Note that the concentration of the quantum dots 50 in the solution to be applied does not necessarily need to be changed, and may be substantially the same.

Furthermore, in the present embodiment, the fourth light-emitting layer 45 may be formed by performing step S7 and step S8 according to the above embodiment. However, in the present embodiment, the heating temperature of the solution in step S8 is set to be higher than the heating temperature of the solution in step S6 described above, and step S7 and step S8 are performed. Thereby, the above-described fourth light-emitting layer 45 can be formed, and the light-emitting layer 28 can be formed.

### Modified Example

### Ternary Compound Semiconductor

A display device according to a modified example of the present embodiment will be described. The display device according to the present modified example has the same configuration as the display device 3 according to the present embodiment except for the material of the inorganic filler 51 of the light-emitting layer 28 included in the light-emitting element 13.

The inorganic filler 51 according to the present modified example includes a ternary compound semiconductor having metal atoms. In particular, in the present modified example, the concentrations of the metal atoms described above gradually increase or gradually decrease in the first inorganic filler 52, the second inorganic filler 54, the third inorganic filler 55, and the fourth inorganic filler 56 in this order. In other words, the inorganic filler 51 according to the present modified example has a concentration gradient of metal atoms in the direction from the anode 21 toward the cathode 26.

For example, the inorganic filler 51 according to the present modified example may contain magnesium atoms, or may contain a sulfide containing zinc atoms. In particular, the inorganic filler 51 may contain zinc magnesium sulfide (ZnMgS or ZnMgS₂) as a sulfide containing both magnesium atoms and zinc atoms.

For example, the first inorganic filler 52, the second inorganic filler 54, the third inorganic filler 55, and the fourth inorganic filler 56 may contain zinc magnesium sulfide whose composition is represented by Zn_{X}Mg_{1-X}S_{1-Y}. Here, X and Y are real numbers satisfying 0≤X≤1 and 0≤Y≤1, respectively, and the value of X increases in the order of the first inorganic filler 52, the second inorganic filler 54, the third inorganic filler 55, and the fourth inorganic filler 56. In this case, the inorganic filler 51 has a concentration gradient in which the concentration of zinc atoms gradually increases in the direction from the anode 21 toward the cathode 26, while having a concentration gradient in which the concentration of magnesium atoms gradually decreases. Note that Y represents the proportion of defects of sulfur atoms in the inorganic filler 51, and may increase in the order of the first inorganic filler 52, the second inorganic filler 54, the third inorganic filler 55, and the fourth inorganic filler 56.

For example, X is equal to 0.3 in the first inorganic filler 52, X is equal to 0.6 in the second inorganic filler 54, X is equal to 0.9 in the third inorganic filler 55, and X is equal to 1 in the fourth inorganic filler 56. In this case, the fourth inorganic filler 56 contains zinc sulfide which is a binary compound semiconductor. As described above, the inorganic filler 51 according to the present embodiment is not limited to a configuration composed only of a ternary compound semiconductor, and may contain a part of a binary compound semiconductor.

The method for manufacturing the light-emitting element 13 according to the present modified example can be the same method as the method for manufacturing the light-emitting element 13 according to the present embodiment except for the method for forming the light-emitting layer 28. In the present modified example, the first light-emitting layer 40, the second light-emitting layer 43, and the third light-emitting layer 44 in the light-emitting layer 28 may be formed by repeatedly performing the above-described steps S5 and S6. Furthermore, in the present modified example, the fourth light-emitting layer 45 may be formed by performing step S7 and step S8 according to the present embodiment.

For example, in the step of forming the first light-emitting layer 40, a first solution containing a plurality of quantum dots 50 and a first inorganic precursor including a plurality of metal sources is applied onto the hole transport layer 23 as step S5. Next, in step S6, the applied first solution is heated to denature the first inorganic precursor into the first inorganic filler 52, thereby forming the first light-emitting layer 40.

In the step of forming the second light-emitting layer 43, a second solution containing a plurality of quantum dots 50 and a second inorganic precursor including a plurality of metal sources is applied onto the hole transport layer 23 as step S5. Here, the proportion of the metal source in the second solution is made different from the proportion of the metal source in the first solution by making the proportion of the metal source in the second inorganic precursor different from that in the first inorganic precursor. Thus, in the next step S6, the second light-emitting layer 43 containing the second inorganic filler 54 having a concentration of metal atoms different from that of the first inorganic filler 52 is formed. Note that in step S6 described above, the heating temperature of the second solution may be higher than the heating temperature of the first solution. Similarly, the light-emitting layer 28 is formed by forming the third light-emitting layer 44 and the fourth light-emitting layer 45.

### Band Diagram of Each Part of Light-Emitting Element

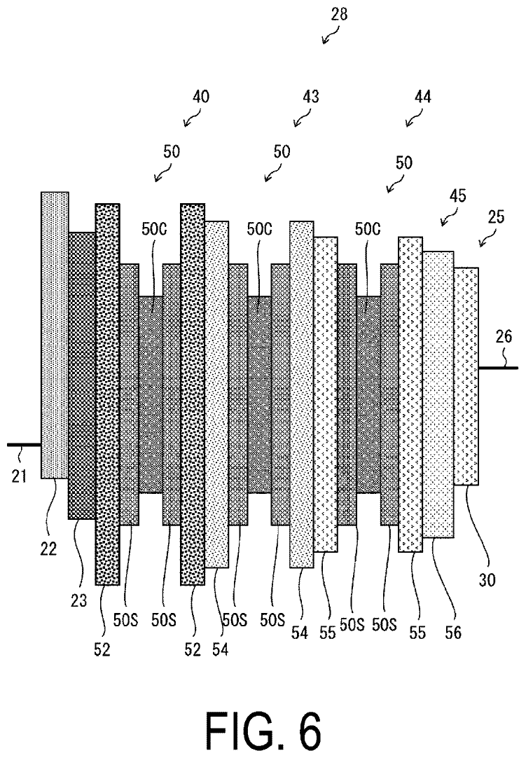

A band gap of each portion of the light-emitting element 13 according to the present modified example will be described with reference to FIG. 6. FIG. 6 is a schematic band diagram illustrating an example of a band gap of each portion of the light-emitting element 13 according to the present modified example. Note that the band diagram of FIG. 6 is assumed to have a vacuum level on the upper side in the drawing. In addition, the left-right direction of the band diagram in FIG. 6 represents the thickness direction in the display direction of the display device 3, and the left side of the drawing is the anode 21 side, and the right side is the cathode 26 side.

The band diagram of FIG. 6 shows respective Fermi levels of the anode 21 and the cathode 26. In addition, band gaps of the hole injection layer 22, the hole transport layer 23, and the electron transport layer 25 are illustrated. In particular, the band diagram of FIG. 6 shows the band gap of the nanoparticles 30 as the band gap of the electron transport layer 25.

Furthermore, the band diagram of FIG. 6 shows the band gaps of the first light-emitting layer 40, the second light-emitting layer 43, the third light-emitting layer 44, and the fourth light-emitting layer 45 as the band gap of the light-emitting layer 28. In particular, the band diagram of FIG. 6 shows the band gaps of the cores 50C and the shells 50S of the quantum dots 50 and the band gaps of the first inorganic filler 52, the second inorganic filler 54, the third inorganic filler 55, and the fourth inorganic filler 56.

Here, in the first light-emitting layer 40, the second light-emitting layer 43, and the third light-emitting layer 44, the inorganic filler 51 fills the spaces between the quantum dots 50. For this reason, in the band diagram of FIG. 6, the band gaps of the first light-emitting layer 40, the second light-emitting layer 43, and the third light-emitting layer 44 can be illustrated such that the band gap of the inorganic filler 51 is positioned at both ends of the band gaps of the quantum dots 50. Note that, in the fourth light-emitting layer 45, only the band gap of the fourth inorganic filler 56 is illustrated.

As illustrated in FIG. 6, the band gaps of the first inorganic filler 52, the second inorganic filler 54, the third inorganic filler 55, and the fourth inorganic filler 56 gradually decrease in this order. In other words, in the present modified example, the band gap of the inorganic filler 51 gradually decreases in the direction from the anode 21 toward the cathode 26. The gradient of the band gap of the inorganic filler 51 described above is realized by a concentration gradient of the metal atoms of the inorganic filler 51 described above.

In particular, the electron affinity of the inorganic filler 51 gradually increases in the direction from the anode 21 toward the cathode 26. In the band diagram of FIG. 6, the electron affinity of each portion corresponds to the distance from the vacuum level to the upper end of the band gap. Thus, in the band diagram of FIG. 6, the lower the upper end of the band gap of a certain layer is located, the higher the electron affinity of the layer is. In other words, the larger the band gap of a certain layer is, the smaller the electron affinity of the layer tends to be.

A barrier of the electron injection from a first layer to a second layer corresponds to the result obtained by subtracting the electron affinity of the second layer from the electron affinity of the first layer. For this reason, in the present modified example, there is a barrier to the injection of electrons from the fourth inorganic filler 56 to the third inorganic filler 55. Similarly, in the present modified example, there is a barrier between the injection of electrons from the third inorganic filler 55 to the second inorganic filler 54 and the injection of electrons from the second inorganic filler 54 to the first inorganic filler 52.

Therefore, the light-emitting element 13 according to the present modified example prevents electrons from moving through the inorganic filler 51 in the direction from the cathode 26 toward the anode 21. Thus, the light-emitting element 13 can increase the ratio of the carriers injected into the quantum dots 50 to the carriers contributing to the reactive current flowing through the inorganic filler 51.

As described above, in the light-emitting element 13 according to the present modified example, the electrons injected from the electron transport layer 25 are prevented from moving between the quantum dots 50 in the light-emitting layer 24, the reactive current in the light-emitting layer 24 is reduced, and the luminous efficiency and reliability are improved.

As the inorganic filler 51 contains magnesium atoms, the band gap of the inorganic filler 51 can be easily designed by adjusting the concentration of magnesium atoms. In addition, since the inorganic filler 51 includes a sulfide containing zinc atoms, it is possible to increase the efficiency in injection of carriers into the quantum dots 50 while increasing the effect of protecting the quantum dots 50.

Display Device having Plurality of Subpixels

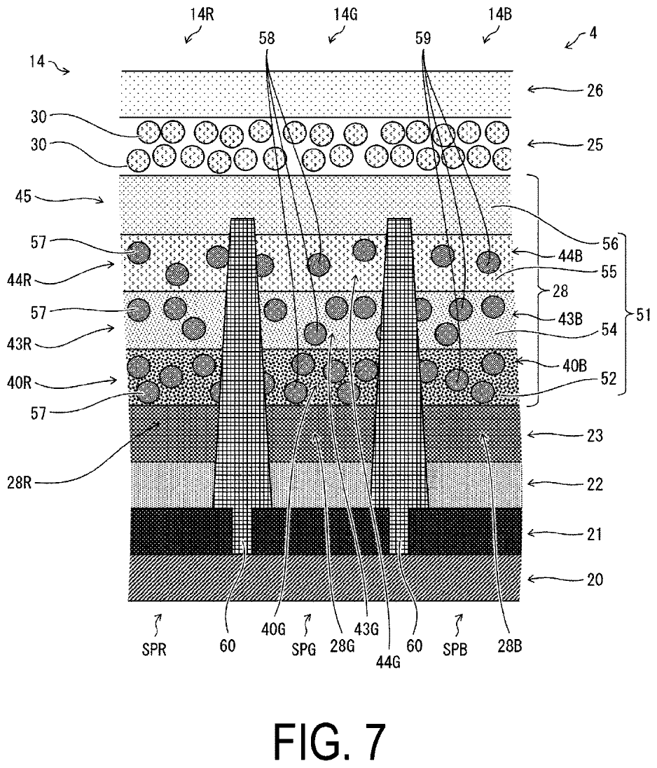

A display device 4 according to the present embodiment will be described with reference to FIG. 7. FIG. 7 is a schematic side cross-sectional view of the display device 4 according to the present embodiment. The display device 4 according to the present embodiment has a light-emitting element 14 in place of the light-emitting element 13 when compared to the display device 3 according to the above embodiment. In addition, the display device 4 according to the present embodiment includes a plurality of subpixels in a plan view, and particularly includes a red subpixel SPR, a green subpixel SPG, and a blue subpixel SPB.

The light-emitting element 14 according to the present embodiment includes a red light-emitting element 14R, a green light-emitting element 14G, and a blue light-emitting element 14B. In a plan view of the substrate 20, the red light-emitting element 14R is located above the red subpixel SPR, the green light-emitting element 14G is located above the green subpixel SPG, and the blue light-emitting element 14B is located above the blue subpixel SPB.

In addition, the light-emitting element 14 includes banks 60 on the substrate 20, unlike the light-emitting element 13 according to the above embodiment. Each of the banks 60 includes, for example, an insulating resin material including polyimide or the like, and is formed from the anode 21 to the middle of the fourth light-emitting layer 45 of the light-emitting layer 28 among the layers of the light-emitting element 14. Thus, the banks 60 divide the layers from the anode 21 of the light-emitting element 14 to the third light-emitting layer 44 of the light-emitting layer 28.

In particular, each layer from the anode 21 of the light-emitting element 14 to the third light-emitting layer 44 of the light-emitting layer 28 is divided into the red subpixel SPR, the green subpixel SPG, and the blue subpixel SPB in the plan view of the substrate 20. Note that, the fourth light-emitting layer 45 of the light-emitting layer 28, the electron transport layer 25, and the cathode 26 may be formed in common to the plurality of subpixels.

In the present embodiment, the light-emitting layer 28 is divided into a red light-emitting layer 28R, a green light-emitting layer 28G, and a blue light-emitting layer 28B by the banks 60. In a plan view of the substrate 20, the red light-emitting layer 28R is located above the red subpixel SPR, the green light-emitting layer 28G is located above the green subpixel SPG, and the blue light-emitting layer 28B is located above the blue subpixel SPB.

In particular, the first light-emitting layer 40 is divided into a first red light-emitting layer 40R, a first green light-emitting layer 40G, and a first blue light-emitting layer 40B. In addition, the second light-emitting layer 43 is divided into a second red light-emitting layer 43R, a second green light-emitting layer 43G, and a second blue light-emitting layer 43B. Furthermore, the third light-emitting layer 44 is divided into a third red light-emitting layer 44R, a third green light-emitting layer 44G, and a third blue light-emitting layer 44B. However, the red light-emitting layer 28R, the green light-emitting layer 28G, and the blue light-emitting layer 28B may include the fourth light-emitting layer 45 in common.

The first red light-emitting layer 40R, the second red light-emitting layer 43R, and the third red light-emitting layer 44R include red quantum dots 57 that emit red light. The first green light-emitting layer 40G, the second green light-emitting layer 43G, and the third green light-emitting layer 44G include green quantum dots 58 that emit green light. The first blue light-emitting layer 40B, the second blue light-emitting layer 43B, and the third blue light-emitting layer 44B include blue quantum dots 59 that emit blue light. Each of the red quantum dots 57, the green quantum dots 58, and the blue quantum dots 59 may have the same configuration as the quantum dots 50 except for the luminescent colors.

Note that red light is light having a light emission central wavelength in a wavelength band longer than 600 nm and shorter than or equal to 780 nm. In addition, green light refers to light having a light emission central wavelength, for example, in a wavelength band of greater than 500 nm and equal to or less than 600 nm. Moreover, blue light refers to light having a light emission central wavelength, for example, in a wavelength band of 400 nm or greater and 500 nm or less.

Except for the above, the red light-emitting layer 28R, the green light-emitting layer 28G, and the blue light-emitting layer 28B have the same configuration as that of the light-emitting layer 28 according to the above embodiment. In other words, also in the present embodiment, each of the first light-emitting layer 40, the second light-emitting layer 43, the third light-emitting layer 44, and the fourth light-emitting layer 45 includes the first inorganic filler 52, the second inorganic filler 54, the third inorganic filler 55, and the fourth inorganic filler 56. Further, in other words, each of the red light-emitting layer 28R, the green light-emitting layer 28G, and the blue light-emitting layer 28B includes the same inorganic filler 51 as the inorganic filler 51 according to the above embodiment.

For this reason, the red light-emitting element 14R includes the substrate 20, the anode 21, the hole injection layer 22, the hole transport layer 23, the red light-emitting layer 28R, the electron transport layer 25, and the cathode 26 that are formed in the red subpixel SPR. The green light-emitting element 14G includes the substrate 20, the anode 21, the hole injection layer 22, the hole transport layer 23, the green light-emitting layer 28G, the electron transport layer 25, and the cathode 26 that are formed in the green subpixel SPG. The blue light-emitting element 14B includes the substrate 20, the anode 21, the hole injection layer 22, the hole transport layer 23, the blue light-emitting layer 28B, the electron transport layer 25, and the cathode 26 that are formed in the blue subpixel SPB.

In the present embodiment, the anode 21, the hole injection layer 22, and the hole transport layer 23 may have the same concept in any of the red subpixel SPR, the green subpixel SPG, and the blue subpixel SPB. However, each anode 21 is electrically connected to a drive circuit formed in each subpixel of the substrate 20.

The display device 4 applies a common potential to the cathode 26, and individually controls voltage application to each anode 21 via a pixel circuit of the substrate 20. As a result, red light from the red light-emitting element 14R, green light from the green light-emitting element 14G, and blue light from the blue light-emitting element 14B are individually extracted from each subpixel to perform color display.

The light-emitting element 14 according to the present embodiment may be manufactured in the same method as that of the light-emitting element 13 according to the above embodiment except for the step of manufacturing the light-emitting layer 28. In the present embodiment, in the step of forming the light-emitting layer 28, for example, a photosensitive resin is formed only in a specific subpixel through photolithography using the photosensitive resin. Next, a solution containing quantum dots is applied to form a film common to a plurality of subpixels. Next, the light-emitting layer 28 may be formed only in a specific subpixel by peeling off the photosensitive resin together with the solution applied as a film. Alternatively, the light-emitting layer 28 may be formed by applying different colors to each of the subpixels of the light-emitting layer 28 by using the ink-jet method or the like.

Each of the red light-emitting element 14R, the green light-emitting element 14G, and the blue light-emitting element 14B according to the present embodiment has the same configuration as that of the light-emitting element 13 according to the above embodiment except for the luminescent color of the quantum dots contained in the light-emitting layer 28. Therefore, for the same reason as that described above, each of the red light-emitting element 14R, the green light-emitting element 14G, and the blue light-emitting element 14B can improve the luminous efficiency while more efficiently enhancing the effect of the inorganic filler 51 of the light-emitting layer 28 protecting the quantum dots 50.

In general, the band gap of the material of the cores of the quantum dots varies depending on the luminescent color of the cores. Therefore, in a light-emitting element including a light-emitting layer containing quantum dots as a light-emitting material, the band gap of a charge transport layer including a hole injection layer, a hole transport layer, and an electron transport layer suitable for the luminescent color of the light-emitting layer is different. Therefore, when the same charge transport layer is applied to all light-emitting elements including light-emitting layers containing quantum dots having different luminescent colors, the carrier balance of the light-emitting layer 28 may not be optimized in some of the light-emitting elements.

In the present embodiment, each of the red light-emitting element 14R, the green light-emitting element 14G, and the blue light-emitting element 14B includes the inorganic fillers 51 having band gaps different from each other in the layering direction. For this reason, in each of the red light-emitting element 14R, the green light-emitting element 14G, and the blue light-emitting element 14B, the light-emitting position of the quantum dots varies in the layering direction depending on the band gap of the contained quantum dots.

Therefore, in the light-emitting element 14, even when the charge transport layer is not optimized for the light-emitting element of each subpixel, the carrier balance of each light-emitting layer 28 can be optimized by making the light-emitting position of the quantum dot different. Therefore, the light-emitting element 14 according to the present embodiment can improve the carrier balance of each light-emitting layer 28 and improve the luminous efficiency while simplifying the manufacturing process by using the charge transport layer in common in each subpixel.

In the present embodiment, although each of the red light-emitting element 14R, the green light-emitting element 14G, and the blue light-emitting element 14B has the same layered structure as that of the light-emitting element 13 according to the above embodiment, the disclosure is not limited thereto. Each of the red light-emitting element 14R, the green light-emitting element 14G, and the blue light-emitting element 14B has, for example, the same layered structure as any one of the above-described light-emitting element 11 or light-emitting element 12.

In the present embodiment, any one of the red light-emitting element 14R, the green light-emitting element 14G, and the blue light-emitting element 14B of the present embodiment may have the same layered structure as the light-emitting element according to any one of the above-described embodiment. In other words, in the present embodiment, some of the red light-emitting elements 14R, the green light-emitting elements 14G, and the blue light-emitting elements 14B may have a structure different from that of the light-emitting elements according to the above-described embodiments.

The disclosure is not limited to the embodiments described above, and various modifications may be made within the scope of the claims. Embodiments obtained by appropriately combining technical approaches disclosed in the different embodiments also fall within the technical scope of the disclosure. Furthermore, novel technical features can be formed by combining the technical approaches disclosed in each of the embodiments.

1. (canceled)

2. A light-emitting element comprising:
an anode;
a cathode; and
a light-emitting layer positioned between the anode and the cathode,
wherein the light-emitting layer includes a plurality of quantum dots and an inorganic filler,
the inorganic filler fills a space between the plurality of quantum dots and includes at least one of a metal sulfide and a metal oxide, and
in the inorganic filler, there is a portion in which a concentration of at least one of sulfur atoms and oxygen atoms on a cathode side is lower than a concentration of the same atoms as the at least one of sulfur atoms and oxygen atoms on an anode side.

3. The light-emitting element according to claim 2,
wherein, in the light-emitting layer, the concentration of the plurality of quantum dots decreases on the cathode side.

4. The light-emitting element according to claim 2,
wherein the light-emitting layer includes, in order from an anode side, a quantum dot layer including the plurality of quantum dots and the inorganic filler, and an inorganic filler layer including only the inorganic filler from among the plurality of quantum dots and the inorganic filler.

5. The light-emitting element according to claim 4,
wherein a film thickness of the inorganic filler layer is 1.2 nm or more.

6. The light-emitting element according to claim 2, further comprising:
a substrate,
wherein the anode, the light-emitting layer, and the cathode are provided on the substrate in order from the substrate side.

7. The light-emitting element according to claim 2,
wherein a density of free electrons in the inorganic filler is 1×10¹⁶ cm⁻³ or less in a region within 1.2 nm in a film thickness direction from an end face of the light-emitting layer on an anode side.

8. The light-emitting element according to claim 2,
wherein a defect density of the sulfur atoms or the oxygen atoms in the inorganic filler is 5×10¹⁷ cm⁻³ or less in a region within 1.2 nm in a film thickness direction from an end face of the light-emitting layer on an anode side.

9. The light-emitting element according to claim 2,
wherein a density of free electrons of the inorganic filler in a region within 1.2 nm in a film thickness direction from an end face of the light-emitting layer on an anode side is one tenth or less of a density of free electrons of the inorganic filler in a region within 1.2 nm in a film thickness direction from an end face of the light-emitting layer on a cathode side.

10. The light-emitting element according to claim 2,
wherein a density of free electrons in the inorganic filler is 1×10¹⁸ cm⁻³ or more and 4×10¹⁹ cm⁻³ or less in a region within 1.2 nm in a film thickness direction from an end face of the light-emitting layer on a cathode side.

11. The light-emitting element according to claim 2,
wherein a defect density of the sulfur atoms or the oxygen atoms in the inorganic filler is 5×10¹⁹ cm⁻³ or more and 2×10²¹ cm⁻³ or less in a region within 1.2 nm in a film thickness direction from an end face of the light-emitting layer on a cathode side.

12. The light-emitting element according to claim 2,
wherein each of the plurality of quantum dots includes a core and a shell as at least one layer covering the core, and
the shell as an outermost layer of each of the plurality of quantum dots of the shell and the inorganic filler include the same material.

13. The light-emitting element according to claim 2,
wherein the inorganic filler includes a binary compound semiconductor.

14. The light-emitting element according to claim 2,
wherein the inorganic filler includes zinc sulfide.

15. The light-emitting element according to claim 2, further comprising:
an electron transport layer positioned between the light-emitting layer and the cathode, the electron transport layer including a plurality of nanoparticles.

16. (canceled)

17. A light-emitting element comprising:
an anode;
a cathode; and
a light-emitting layer positioned between the anode and the cathode,
wherein the light-emitting layer includes
a plurality of quantum dots and an inorganic filler that includes a chalcogenide and fills a space between the plurality of quantum dots, and
in the inorganic filler, a concentration of atoms of a chalcogen element decreases in a direction from the anode toward the cathode.

18. A light-emitting element comprising:
an anode;
a cathode; and
a light-emitting layer positioned between the anode and the cathode,
wherein the light-emitting layer includes a plurality of quantum dots and an inorganic filler,
the inorganic filler fills a space between the plurality of quantum dots, includes a ternary compound semiconductor including a metal atom, and has a concentration gradient of the metal atom in a direction from the anode toward the cathode, and
a band gap of the inorganic filler becomes smaller in the direction from the anode toward the cathode.

19. The light-emitting element according to claim 18,
wherein the inorganic filler includes a magnesium atom.

20. The light-emitting element according to claim 18,
wherein the inorganic filler includes a sulfide including a zinc atom.

21. A display device comprising:
a red light-emitting element;
a green light-emitting element; and
a blue light-emitting element,
wherein at least one of the red light-emitting element, the green light-emitting element, and the blue light-emitting element is the light-emitting element according to claim 2.

22. (canceled)

23. (canceled)
